(19) United States
(12) Patent Application Publication
(10) Pub. No.: US 2025/0280643 A1
(43) Pub. Date: Sep. 4, 2025

(54) DISPLAY PANEL AND DISPLAY APPARATUS

(71) Applicant: Tianma Advanced Display Technology Institute (Xiamen) Co., Ltd., Xiamen (CN)

(72) Inventor: Liwei ZHANG, Xiamen (CN)

(21) Appl. No.: 19/209,741

(22) Filed: May 15, 2025

(30) Foreign Application Priority Data
Nov. 14, 2024 (CN) 202411633988.5

(51) Int. Cl. H10H 29/49; H10H 29/39

(52) U.S. Cl. CPC H10H 29/49; H10H 29/39

(57) ABSTRACT

Provided are a display panel and a display apparatus. The display panel comprises a substrate and pixel circuits on one side of the substrate. At least one of the pixel circuits comprises a driving transistor, a data writing transistor, and an anode reset transistor. The data writing transistor has a gate electrically connected to a first scan line, a first electrode electrically connected to a data line, and a second electrode electrically connected to a first electrode of the driving transistor. The anode reset transistor has a gate electrically connected to the first scan line, a first electrode electrically connected to a reset line, and a second electrode electrically connected to a light-emitting element. The anode reset transistor and the data writing transistor of a same pixel circuit are electrically connected to a same first scan line.

### CROSS-REFERENCE TO RELATED APPLICATION

The present disclosure claims priority to Chinese Patent Application No. 202411633988.5 entitled “DISPLAY PANEL AND DISPLAY APPARATUS” filed on Nov. 14, 2024, the content of which is incorporated herein by reference in its entirety.

### TECHNICAL FIELD

The present disclosure relates to the technical field of display, and in particular, to a display panel and a display apparatus.

### BACKGROUND

A display panel includes pixel circuits and light-emitting elements. The layout design of the pixel circuits is a key factor affecting circuit performance, display panel resolution, and the like. Therefore, how to further optimize the layout design of the pixel circuits becomes a technical problem to be solved urgently at present.

### SUMMARY

Provided are a display panel and a display apparatus, in which the pixel circuits feature an improved layout design.

In a first aspect, an embodiment of the present disclosure provides a display panel including display panel, including a substrate and pixel circuits on one side of the substrate, where at least one of the pixel circuits includes:
a driving transistor;
a data writing transistor having a gate electrically connected to a first scan line, a first electrode electrically connected to a data line, and a second electrode electrically connected to a first electrode of the driving transistor; and
an anode reset transistor having a gate electrically connected to the first scan line, a first electrode electrically connected to a reset line, and a second electrode electrically connected to a light-emitting element;
where the anode reset transistor and the data writing transistor of a same pixel circuit are electrically connected to a same first scan line.

In a second aspect, based on the same inventive concept, an embodiment of the present disclosure further provides a display apparatus including a display panel, where the display panel includes a substrate and pixel circuits on one side of the substrate, where at least one of the pixel circuits includes:
a driving transistor;
a data writing transistor having a gate electrically connected to a first scan line, a first electrode electrically connected to a data line, and a second electrode electrically connected to a first electrode of the driving transistor; and
an anode reset transistor having a gate electrically connected to the first scan line, a first electrode electrically connected to a reset line, and a second electrode electrically connected to a light-emitting element;
where the anode reset transistor and the data writing transistor of a same pixel circuit are electrically connected to a same first scan line.

### BRIEF DESCRIPTION OF DRAWINGS

In order to more clearly illustrate the technical solutions in the embodiments of the present disclosure or in the prior art, the following briefly introduces the drawings that are required to be used in the description of the embodiments or the prior art. Obviously, the drawings in the description below are some of the embodiments of the present disclosure. For those skilled in the art, other drawings can be obtained from these drawings without any creative labor.

FIG. 1 is a structural schematic diagram of a display panel provided by an embodiment of the present disclosure;

FIG. 2 is a schematic diagram of a circuit structure of a pixel circuit provided by an embodiment of the present disclosure;

FIG. 3 is a schematic diagram of a film layer structure of a display panel provided by an embodiment of the present disclosure;

FIG. 4 is a schematic diagram of another film layer structure of a display panel provided by an embodiment of the present disclosure;

FIG. 5 is a schematic diagram of yet another film layer structure of a display panel provided by an embodiment of the present disclosure;

FIG. 6 is a schematic diagram of a further film layer structure of a display panel provided by an embodiment of the present disclosure;

FIG. 7 is a cross-sectional view taken along an A1-A2 direction in FIG. 6;

FIG. 8 is a schematic diagram of a further film layer structure of a display panel provided by an embodiment of the present disclosure;

FIG. 9 is a cross-sectional view taken along a B1-B2 direction in FIG. 8;

FIG. 10 is a schematic diagram of a further film layer structure of a display panel provided by an embodiment of the present disclosure;

FIG. 11 is a schematic diagram of a further film layer structure of a display panel provided by an embodiment of the present disclosure;

FIG. 12 is a schematic diagram of a further film layer structure of a display panel provided by an embodiment of the present disclosure;

FIG. 13 is a schematic diagram of a further film layer structure of a display panel provided by an embodiment of the present disclosure;

FIG. 14 is a schematic diagram of a further film layer structure of a display panel provided by an embodiment of the present disclosure;

FIG. 15 is a schematic diagram of a further film layer structure of a display panel provided by an embodiment of the present disclosure;

FIG. 16 is another structural schematic diagram of a display panel provided by an embodiment of the present disclosure;

FIG. 17 is a structural schematic diagram of a display panel in the related art;

FIG. 18 is a schematic diagram of a cross-sectional structure of a display panel provided by an embodiment of the present disclosure;

FIG. 19 is an arrangement comparison diagram of data lines provided by an embodiment of the present disclosure;

FIG. 20 is a schematic diagram of a further film layer structure of a display panel provided by an embodiment of the present disclosure;

FIG. 21 is another structural comparison diagram of data lines provided by an embodiment of the present disclosure;

FIG. 22 is a schematic diagram of a further film layer structure of a display panel provided by an embodiment of the present disclosure;

FIG. 23 is a schematic diagram of a further film layer structure of a display panel provided by an embodiment of the present disclosure;

FIG. 24 is a schematic diagram of a further film layer structure of a display panel provided by an embodiment of the present disclosure;

FIG. 25 is a schematic diagram of a further film layer structure of a display panel provided by an embodiment of the present disclosure;

FIG. 26 is a cross-sectional view taken along a C1-C2 direction in FIG. 25;

FIG. 27 is a schematic diagram of a further film layer structure of a display panel provided by an embodiment of the present disclosure;

FIG. 28 is a schematic diagram of another cross-sectional structure of a display panel provided by an embodiment of the present disclosure;

FIG. 29 is a schematic diagram of a further film layer structure of a display panel provided by an embodiment of the present disclosure;

FIG. 30 is a further structural schematic diagram of a display panel provided by an embodiment of the present disclosure;

FIG. 31 is a schematic diagram of a further film layer structure of a display panel provided by an embodiment of the present disclosure;

FIG. 32 is a structural schematic diagram of a semiconductor layer corresponding to FIG. 3;

FIG. 33 is a structural schematic diagram of a first metal layer corresponding to FIG. 3;

FIG. 34 is a structural schematic diagram of a second metal layer corresponding to FIG. 3;

FIG. 35 is a structural schematic diagram of a third metal layer corresponding to FIG. 3;

FIG. 36 is a structural schematic diagram of a fourth metal layer corresponding to FIG. 3; and

FIG. 37 is a structural schematic diagram of a display apparatus provided by an embodiment of the present disclosure.

### DESCRIPTION OF EMBODIMENTS

In order to better understand the technical solutions of the present disclosure, the embodiments of the present disclosure will be described in detail below in conjunction with the accompanying drawings.

It should be clear that the described embodiments are only a part of, rather than all of, the embodiments of the present disclosure. All other embodiments obtained by those of ordinary skill in the art based on the embodiments of the present disclosure without creative efforts shall fall within the protection scope of the present disclosure.

The terms used in the embodiments of the present disclosure are only for the purpose of describing specific embodiments and are not intended to limit the present disclosure. The singular forms “a,” “an,” and “the” used in the embodiments of the present disclosure and the appended claims are also intended to include plural forms, unless the context clearly indicates otherwise.

It should be understood that the term “and/or” used herein is merely an association relationship describing associated objects, indicating that there can be three relationships. For example, A and/or B can represent the following three situations: A exists alone, both A and B exist simultaneously, and B exists alone. In addition, the character “/” herein generally indicates an “or” relationship between the associated objects before and after it.

An embodiment of the present disclosure provides a display panel, which can be a light-emitting diode (LED) display panel, for example a micro-LED display panel.

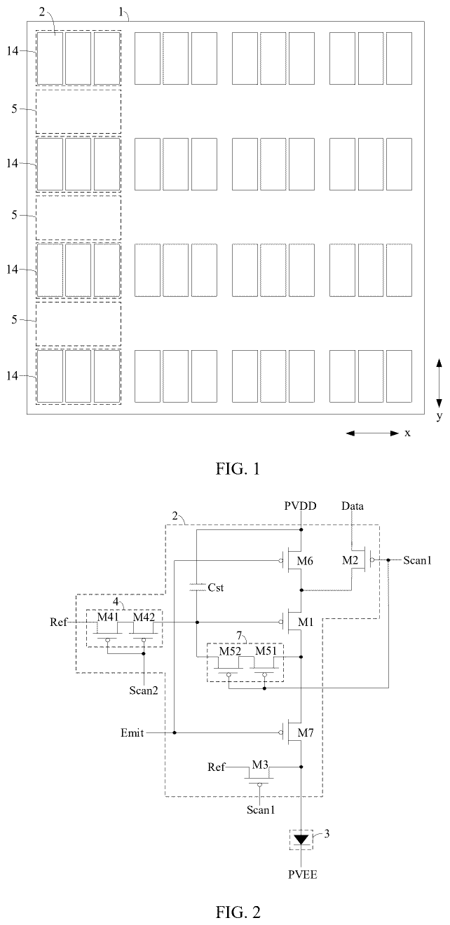

As shown in FIG. 1, FIG. 1 is a structural schematic diagram of a display panel provided by an embodiment of the present disclosure, the display panel includes a substrate 1 and pixel circuits 2 located on one side of the substrate 1.

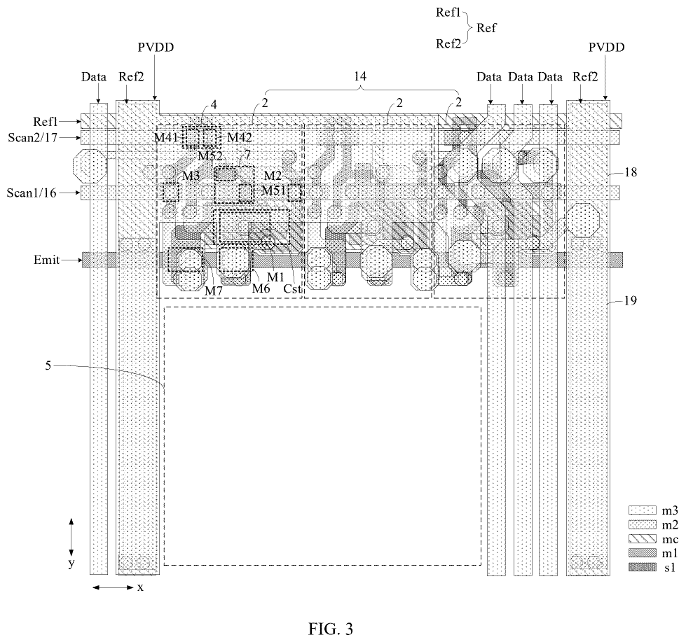

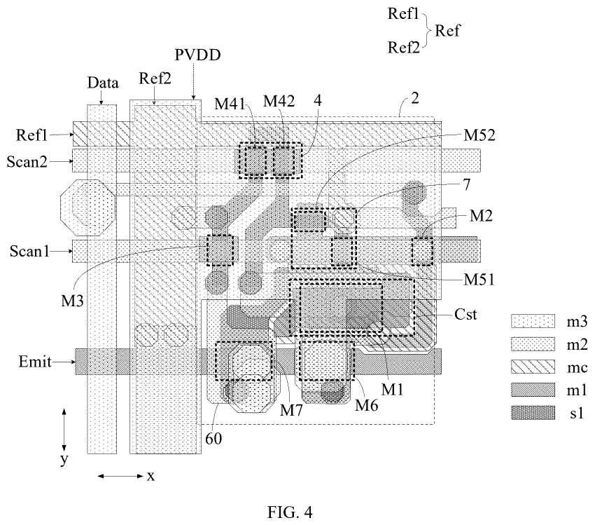

As shown in FIGS. 2 to 4, FIG. 2 is a schematic diagram of a circuit structure of a pixel circuit 2 provided by an embodiment of the present disclosure, FIG. 3 is a schematic diagram of a film layer structure of a display panel provided by an embodiment of the present disclosure, and FIG. 4 is a schematic diagram of another film layer structure of a display panel provided by an embodiment of the present disclosure. The pixel circuit 2 includes a driving transistor M1, a data writing transistor M2, and an anode reset transistor M3. The data writing transistor M2 has a gate electrically connected to a first scan line Scan1, a first electrode electrically connected to a data line Data, and a second electrode electrically connected to a first electrode of the driving transistor M1. The anode reset transistor M3 has a gate electrically connected to the first scan line Scan1, a first electrode electrically connected to a reset line Ref, and a second electrode electrically connected to a light-emitting element 3.

The anode reset transistor M3 and the data writing transistor M2 of a same pixel circuit 2 are electrically connected to a same first scan line Scan1.

Referring to FIGS. 2 to 4, the pixel circuit 2 further includes a gate reset module 4. A control terminal of the gate reset module 4 is electrically connected to a second scan line Scan2, a first terminal of the gate reset module 4 is electrically connected to the reset line Ref, and a second terminal of the gate reset module 4 is electrically connected to a gate of the driving transistor M1.

In the related art, a first scan signal received by a previous pixel row is the same as a second scan signal received by a next pixel row. When enabling both the anode reset transistor M3 and the data writing transistor M2 in the pixel circuit 2 to receive the first scan signal, in the related art, the data writing transistor M2 is connected to the first scan line Scan1 corresponding to a current pixel row, and the anode reset transistor M3 is placed at the position of the next pixel row so that it is connected to the second scan line Scan2 corresponding to the next pixel row.

However, in the embodiments of the present disclosure, the connection manner between the anode reset transistor M3 and the scan line is changed, and the anode reset transistor M3 is connected to the first scan line Scan1 corresponding to the current pixel row. That is, “the anode reset transistor M3 and the data writing transistor M2 of a same pixel circuit 2 are electrically connected to a same first scan line Scan1”, as mentioned above.

In this connection manner, referring to FIGS. 3 and 4, the anode reset transistor M3 and the data writing transistor M2 in the same pixel circuit 2 are located on the same side of the driving transistor M1; the anode reset transistor M3 and other transistors in the pixel circuit 2 where the anode reset transistor M3 is located are arranged more compactly, which not only compresses the layout space of the pixel circuit 2 and improves the PPI but also reduces the length of the connection lines between the anode reset transistor M3 and other transistors in the pixel circuit where the anode reset transistor M3 is located, reducing the signal voltage drop. Moreover, with the above design, the second scan line Scan2 corresponding to the current pixel row only needs to be used to provide the second scan signal to the current pixel row and does not need to be used to provide the first scan signal to the previous pixel row. Therefore, the limitation between the first scan signal and the second scan signal can be eliminated. The timing of the first scan signal and the second scan signal can be the same or different, providing higher design flexibility.

Regarding “the anode reset transistor M3 and other transistors in the pixel circuit 2 where the anode reset transistor M3 is located are arranged more compactly” as mentioned above, in a specific structure, referring to FIGS. 2 and 4, the pixel circuit further includes a second light-emitting control transistor M7, and a second electrode of the second light-emitting control transistor M7 is electrically connected to the light-emitting element 3. Based on the above design, the anode reset transistor M3 may be close to the second light-emitting control transistor M7. When the anode reset transistor M3 is electrically connected to the second light-emitting control transistor M7 through a connection trace 60 located in a semiconductor layer s1 or a metal layer, the connection trace 60 can be designed shorter, which in turn can, to a certain extent, save the layout space and reduce the voltage drop of the signal during transmission.

In addition, the embodiments of the present disclosure can also be applied to transparent display. Referring to FIGS. 1 and 3, the display panel is a transparent display panel and further includes a light-transmitting region 5. By adopting the above technical solutions, the layout space of the pixel circuit 2 can be compressed, and in turn a part of the region can be released as the light-transmitting region 5, thereby increasing the transmittance of the display panel. Further, since the anode reset transistor M3 is located in the region of the current pixel row, when the anode reset transistor M3 is connected to the second light-emitting control transistor M7 through the connection trace 60, the connection trace 60 does not need to cross the interval between two adjacent pixel rows, and thus it does not occupy the light-transmitting area, further increasing the transmittance.

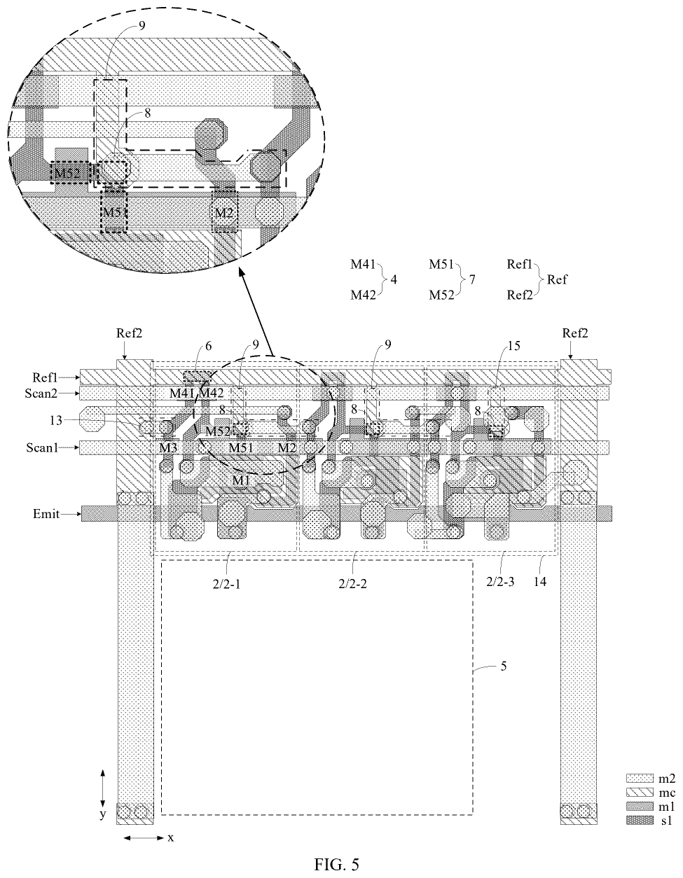

In a feasible implementation, in conjunction with FIG. 2 and as shown in FIG. 5, FIG. 5 is a schematic diagram of yet another film layer structure of a display panel provided by an embodiment of the present disclosure, the pixel circuit 2 further includes a gate reset module 4 including a first reset transistor M41 and a second reset transistor M42. A gate of the first reset transistor M41 and a gate of the second reset transistor M42 are both electrically connected to the second scan line Scan2. A first electrode of the first reset transistor M41 is electrically connected to the reset line Ref. A second electrode of the first reset transistor M41 is electrically connected to a first electrode of the second reset transistor M42 through a first connection line 6, and a second electrode of the second reset transistor M42 is electrically connected to the gate of the driving transistor M1.

The first scan line Scan1 and the second scan line Scan2 extend along a first direction x.

The reset line Ref includes a first reset sub-line Ref1. The first reset sub-line Ref1 extends along the first direction x and is located on one side of the second scan line Scan2 away from the first scan line Scan1. In a direction perpendicular to a plane of the substrate 1, the first reset sub-line overlaps with the first connection line 6.

A reset signal, which is a DC constant-voltage signal, is transmitted on the first reset sub-line Ref1. Since the first reset sub-line overlaps with the first connection line 6, the first reset sub-line can function as the shielding metal for the first connection line 6 to stabilize the potential at the intermediate node between the first reset transistor M41 and the second reset transistor M42, which in turn reduces the influence of the leakage current of the gate reset module 4 on the stability of the gate potential of the driving transistor M1; and on the other hand, when the line width of the first reset sub-line is fixed, the overlap between the first reset sub-line Ref1 and the first connection line 6 indicates that the first reset sub-line Ref1 is closer to the second scan line Scan2. In this way, the overall layout space occupied by the pixel circuit 2 and the signal lines in a second direction y can be reduced, improving the PPI. The second direction y intersects with the first direction x.

In addition, when the embodiments of the present disclosure are applied to transparent display, referring to FIGS. 1 and 3, the display panel further includes a light-transmitting region 5. Based on the above-described structure, the overall layout space occupied by the pixel circuit 2 and the signal lines in the second direction y can be reduced. As a result, a part of the space in the second direction y can be released as the light-transmitting region 5. In other words, the size of the light-transmitting region 5 in the second direction y can be increased, which enlarges the light-transmitting area and ensures that the display panel has a sufficiently high transmittance.

In a feasible implementation, in conjunction with FIGS. 2 and 5, the pixel circuit 2 further includes a threshold compensation module 7. The threshold compensation module includes a first compensation transistor M51 and a second compensation transistor M52. A gate of the first compensation transistor M51 and a gate of the second compensation transistor M52 are both electrically connected to the first scan line Scan1. A first electrode of the first compensation transistor M51 is electrically connected to the second electrode of the driving transistor M1. A second electrode of the first compensation transistor M51 is electrically connected to a first electrode of the second compensation transistor M52 through a second connection line 8, and a second electrode of the second compensation transistor M52 is electrically connected to the gate of the driving transistor M1.

At least one of the anode reset transistors M3 in at least some of the pixel circuits 2 is electrically connected to the first reset sub-line through a third connection line 9. In the direction perpendicular to the plane of the substrate 1, the third connection line 9 overlaps with the second connection line 8.

The third connection line 9 serves as the connection trace between the anode reset transistor M3 and the first reset sub-line and transmits a stable DC constant-voltage signal. Since the third connection line 9 overlaps with the second connection line 8, the third connection line 9 also functions as the shielding metal for the second connection line 8 to stabilize the potential at the intermediate node between the first compensation transistor M51 and the second compensation transistor M52, which in turn reduces the influence of the leakage current of the threshold compensation module on the stability of the gate potential of the driving transistor M1.

In the embodiments of the present disclosure, the pixel circuit 2 where the anode reset transistor M3 connected to the third connection line 9 is located and the pixel circuit 2 where the second connection line 8 overlapping with the third connection line 9 is located can be the same pixel circuit 2 or different pixel circuits 2.

For example, referring to FIG. 5, for a same third connection line 9, the pixel circuit 2 where the anode reset transistor M3 connected to the third connection line 9 is located is adjacent to the pixel circuit 2 where the second connection line 8 overlapping with the third connection line 9 is located in the first direction x.

In other words, the anode reset transistor M3 connected to the third connection line 9 is located in one pixel circuit 2, and the second connection line 8 overlapping with the third connection line 9 is located in another pixel circuit 2. These two pixel circuits 2 are adjacent in the first direction x.

Exemplarily, referring to FIG. 5, the pixel circuits 2 includes a first pixel circuit 2-1, a second pixel circuit 2-2, and a third pixel circuit 2-3. The second pixel circuit 2-2 is located between the first pixel circuit 2-1 and the third pixel circuit 2-3. FIG. 5 schematically shows two third connection lines 9. For one of the third connection lines 9, the anode reset transistor M3 connected to it is located in the second pixel circuit 2-2, and the second connection line 8 overlapping with it is located in the first pixel circuit 2-1. For the other third connection line 9, the anode reset transistor M3 connected to it is located in the third pixel circuit 2-3, and the second connection line 8 overlapping with it is located in the second pixel circuit 2-2.

In other words, the pixel circuit 2 where the anode reset transistor M3 connected to the third connection line 9 is located is defined as the first circuit corresponding to the third connection line 9, and the pixel circuit 2 where the second connection line 8 overlapping with the third connection line 9 is located is defined as the second circuit corresponding to the third connection line 9. The first and second circuits corresponding to the same third connection line 9 are adjacent in the first direction x.

Exemplarily, referring to FIG. 5, the first circuit corresponding to one of the third connection lines 9 is the second pixel circuit 2-2, and the second circuit corresponding to the one of the third connection lines 9 is the first pixel circuit 2-1. The first circuit corresponding to the other third connection line 9 is the third pixel circuit 2-3, and the second circuit corresponding to the other third connection line 9 is the second pixel circuit 2-2.

In this design manner, after being led out from the anode reset transistor M3 of a certain pixel circuit 2, the third connection line 9 only needs to extend along the first direction x to the second connection line 8 in the adjacent pixel circuit 2. After overlapping with the second connection line 8, the third connection line 9 can turn upward to connect to the first reset sub-line Ref1. For example, taking the third connection line 9 electrically connected to the anode reset transistor M3 in the second pixel circuit 2-2 as shown in FIG. 5 as an example, after being led out from the anode reset transistor M3 of the second pixel circuit 2-2, the third connection line 9 extends along the first direction x to the second connection line 8 in the first pixel circuit 2-1. After overlapping with the second connection line 8, the third connection line 9 can turn upward to connect to the first reset sub-line Ref1. In this structure, the third connection line 9 has a shorter extension length and a correspondingly smaller load, and the signal voltage drop is also reduced.

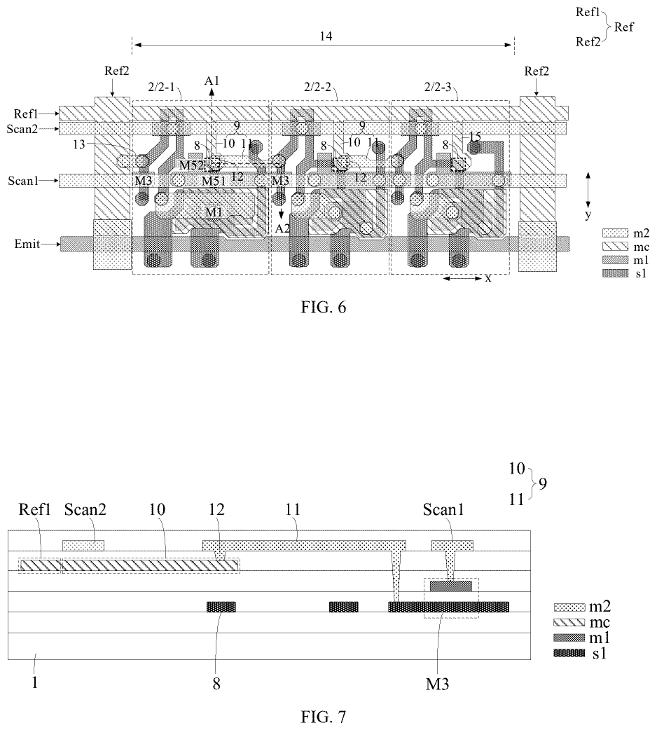

Regarding the position of the film layer where the third connection line 9 is located, in a feasible implementation, as shown in FIGS. 6 and 7, FIG. 6 is a schematic diagram of further film layer structure of a display panel provided by an embodiment of the present disclosure, and FIG. 7 is a cross-sectional view taken along a direction A1-A2 in FIG. 6. The display panel includes a semiconductor layer s1, a first metal layer m1 on one side of the semiconductor layer s1 away from the substrate 1, a second metal layer mc on one side of the first metal layer m1 away from the substrate 1, and a third metal layer m2 on one side of the second metal layer mc away from the substrate 1.

The first connection line 6 and the second connection line 8 are located in the semiconductor layer s1. The gate of the driving transistor M1 is located in the first metal layer m1, and the first reset sub-line is located in the second metal layer mc.

The third connection line 9 includes a first sub-part 10 and a second sub-part 11. The first sub-part 10 is connected to the first reset sub-line Ref1, and the second sub-part 11 is connected between the first sub-part 10 and the anode reset transistor M3. The first sub-part 10 is located in the second metal layer mc, the second sub-part 11 is located in the third metal layer m2, and in the direction perpendicular to the plane of the substrate 1, the first sub-part 10 overlaps with the second connection line 8.

In the current film layer design of the display panel, compared with the first metal layer m1 and the second metal layer mc, the third metal layer m2 has a greater film thickness, and uses a metal material with a lower resistance. For example, the third metal layer m2 is a laminated structure of titanium-aluminum-titanium, and thus the impedance of the third metal layer m2 is lower.

In the embodiments of the present disclosure, the third connection line 9 is made of two layers of metal. The third connection line 9 includes the first sub-part 10 and the second sub-part 11 located in different layers. The first sub-part 10 is connected to the first reset sub-line Ref1 and overlaps with the second connection line 8. The first sub-part 10 is located in the second metal layer mc. On the one hand, the first sub-part can be directly connected to the first reset sub-line without a drilling process; and on the other hand, the film layer spacing between the first sub-part 10 and the second connection line 8 can be reduced, which in turn achieves a better effect in stabilizing the potential of the second connection line 8. Further, the first sub-part 10 is switched to the second sub-part 11, which is located in the third metal layer m2. On the one hand, the low impedance characteristic of the third metal layer m2 can be utilized to reduce the load of the third connection line 9, which in turn reduces the signal voltage drop; and on the other hand, in the current manufacturing process, there is no drilling process between the second metal layer mc and the semiconductor layer s1, while there is a drilling process between the third metal layer m2 and the semiconductor layer s1. When the first sub-part 10 crosses over to the second sub-part 11, and the third connection line 9 is connected to the anode reset transistor M3, a connection via-hole can be directly designed in the existing drilling process between the third metal layer m2 and the semiconductor layer s1, without adding other drilling processes or adding additional mask plates, reducing the process cost.

Further, referring to FIGS. 6 and 7, the first sub-part 10 and the second sub-part 11 are electrically connected through a first connection via-hole 12. In the direction perpendicular to the plane of the substrate 1, the first connection via-hole 12 overlaps with the second connection line 8. Exemplarily, the first sub-part 10 extends along the second direction y, the second sub-part 11 extends along the first direction x, and they are connected through drilling above the second connection line 8.

As mentioned above, the impedance of the third metal layer m2 is smaller. The overlap of the first connection via-hole 12 with the second connection line 8 means that the first sub-part 10 can be switched to the third metal layer m2 above the second connection line 8. In this way, the length ratio of the second sub-part 11 in the third connection line 9 can be increased, and the load of the third connection line 9 can be further reduced.

Of course, in other optional implementations of the present disclosure, in the direction perpendicular to the plane of the substrate 1, the first connection via-hole 12 may not overlap with the second connection line 8. For example, the first sub-part 10 first extends along the second direction y to overlap with the second connection line 8, then turns along the first direction x to one side of the second connection line 8, and is switched to the third metal layer m2 on the one side of the second connection line 8.

In a feasible implementation, referring to FIGS. 5 and 6, the reset line Ref further includes a second reset sub-line Ref2. The second reset sub-line Ref2 extends along the second direction y and is electrically connected to the first reset sub-line Ref1. In this case, the first reset sub-line and the second reset sub-line Ref2 intersect to form a grid-like structure, and the overall load of the reset line Ref is smaller.

The pixel circuits 2 include the first pixel circuit 2-1 adjacent to the second reset sub-line Ref2. The anode reset transistor M3 in the first pixel circuit 2-1 is electrically connected to the second reset sub-line Ref2 through a fourth connection line 13.

The first pixel circuit 2-1 being adjacent to the second reset sub-line Ref2 means that they are relatively close to each other. In this case, the way of connecting the first pixel circuit 2-1 to the second reset sub-line Ref2 may be selected so that the first pixel circuit 2-1 can receive the reset signal, thereby facilitating the connection wiring between the first pixel circuit 2-1 and the reset line Ref.

In a feasible implementation, referring to FIGS. 5 and 6, the pixel circuits 2 includes a first pixel circuit 2-1, a second pixel circuit 2-2, and a third pixel circuit 2-3.

The display panel includes a pixel circuit group 14 including the first pixel circuit 2-1, the second pixel circuit 2-2, and the third pixel circuit 2-3 arranged along the first direction x. Along the first direction x, two adjacent second reset sub-lines Ref2 are spaced from each other by the pixel circuit group 14.

In the first pixel circuit 2-1, a distance between the anode reset transistor M3 and the second reset sub-line Ref2 is less than a distance between the data writing transistor M2 and the second reset sub-line Ref2.

In other words, when two adjacent second reset sub-lines Ref2 are spaced from each other by the pixel circuit group 14, the first pixel circuit 2-1 and the third pixel circuit 2-3 in the pixel circuit group 14 are both adjacent to the second reset sub-lines Ref2. For these two pixel circuits 2, the anode reset transistor M3 in the first pixel circuit 2-1 is closer to the second reset sub-line Ref2. Therefore, the first pixel circuit 2-1 is selected to be connected to the second reset sub-line Ref2, and the connection distance between the pixel circuit 2 and the second reset sub-line Ref2 is shorter.

The distance between the anode reset transistor M3 and the second reset sub-line Ref2 can be defined by the distance between the channel of the anode reset transistor M3 and the second reset sub-line Ref2. Similarly, the distance between the data writing transistor M2 and the second reset sub-line Ref2 can be defined by the distance between the channel of the data writing transistor M2 and the second reset sub-line Ref2.

Further, the second pixel circuit 2-2 is electrically connected to the third connection line 9, and in the direction perpendicular to the plane of the substrate 1, the third connection line 9 connected to the second pixel circuit 2-2 overlaps with the second connection line 8 in the first pixel circuit 2-1. The third pixel circuit 2-3 is electrically connected to the third connection line 9, and in the direction perpendicular to the plane of the substrate 1, the third connection line 9 connected to the third pixel circuit 2-3 overlaps with the second connection line 8 in the second pixel circuit 2-2.

The display panel further includes a shielding part 15 electrically connected to the reset line Ref. In the direction perpendicular to the plane of the substrate 1, the shielding part 15 overlaps with the second connection line 8 in the third pixel circuit 2-3.

When it is realized that each of the pixel circuits 2 in the pixel circuit group 14 can be electrically connected to the reset line Ref and the second connection line 8 in each of the pixel circuits 2 can be shielded, the above-mentioned overall design formed by the third connection line 9, the fourth connection line 13, and the shielding part 15 adopts a more reasonable wiring manner, and the overall layout design of the pixel circuit 2 is better.

In the embodiments of the present disclosure, the fourth connection line 13 is located in the third metal layer m2. The fourth connection line 13 and the second sub-part 11 of the third connection line 9 are arranged along the first direction x, and a length of the fourth connection line 13 may be less than a length of the second sub-part 11. The shielding part 15 is connected to the first reset sub-line and located in the second metal layer mc, and the shape of the shielding part 15 may be consistent with the shape of the first sub-part 10 of the third connection line 9.

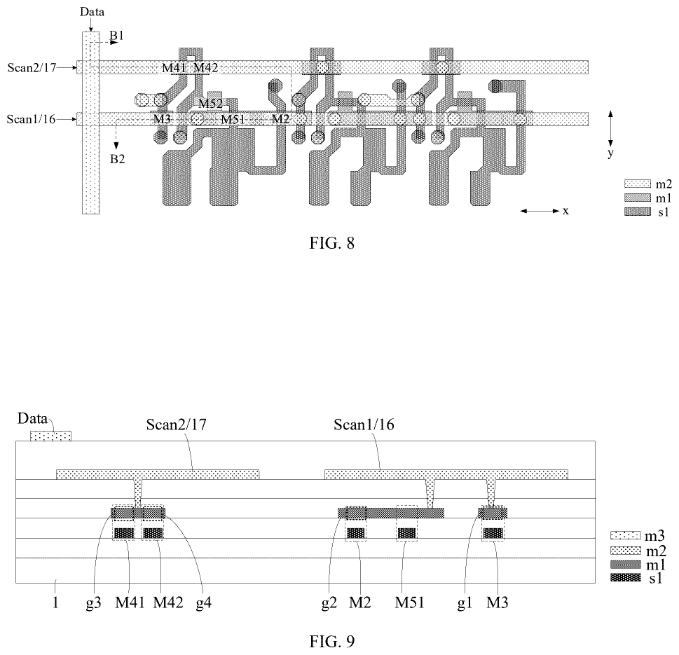

In a feasible implementation, as shown in FIGS. 8 and 9, FIG. 8 is a schematic diagram of a further film layer structure of a display panel provided by an embodiment of the present disclosure, and FIG. 9 is a cross-sectional view taken along a direction B1-B2 in FIG. 8. The display panel includes a first metal layer m1, and the gate g1 of the anode reset transistor M3 and/or the gate g2 of the data writing transistor M2 are/is located in the first metal layer m1.

The first scan line Scan1 includes a first part 16 electrically connected to the gate g1 of the anode reset transistor M3 and/or the gate g2 of the data writing transistor M2. The first part 16 is on one side of the first metal layer m1 away from the substrate 1. For example, the first part 16 may be located in the third metal layer m2.

The gate g3 of the first reset transistor M41 and/or the gate g4 of the second reset transistor M42 are/is located in the first metal layer m1. The second scan line Scan2 includes a second part 17 electrically connected to the gate g3 of the first reset transistor M41 and/or the gate g4 of the second reset transistor M42. The second part 17 is on the one side of the first metal layer m1 away from the substrate 1. For example, the second part 17 may be located in the third metal layer m2.

In the conventional design of the scan lines, the scan lines are located in the first metal layer m1, and a part of the scan lines are reused with the gates of the transistors connected to them. In the embodiments of the present disclosure, at least some of the scan lines are disposed in other metal layers, and the gates of the transistors are connected to these film layers through via-holes. In this way, some metal layers with lower impedance can be selected to reduce the overall loads of the scan lines. For example, the first part 16 and the second part 17 are located in the third metal layer m2. Such a structure is particularly suitable for large-size display panels, where the scan lines are very long and the corresponding loads are very large. Wiring at least some of the scan lines in the third metal layer m2 can effectively reduce the loads of the scan lines.

The first part 16 and the second part 17 may be continuous traces extending along the first direction x. That is, in the direction perpendicular to the plane of the substrate 1, the first part 16 overlaps with a plurality of pixel circuits 2 arranged along the first direction x, and the second part 17 overlaps with a plurality of pixel circuits 2 arranged along the first direction x.

Alternatively, the first scan line Scan1 may include a plurality of first parts 16, and there is a gap between adjacent first parts 16. In the direction perpendicular to the plane of the substrate 1, at least a part of the gate g1 of the anode reset transistor M3 does not overlap with the first part 16, and/or at least a part of the gate g2 of the data writing transistor M2 does not overlap with the first part 16.

The second scan line Scan2 may also include a plurality of second parts 17, and there is a gap between adjacent second parts 17. In the direction perpendicular to the plane of the substrate 1, at least a part of the gate g3 of the first reset transistor M41 does not overlap with the second part 17, and at least a part of the gate g4 of the second reset transistor M42 does not overlap with the second part 17.

When the first part 16 and the second part 17 are located in the third metal layer m2, referring to FIGS. 8 and 9, the display panel further includes a fourth metal layer m3, and the fourth metal layer m3 is located on one side of the third metal layer m2 away from the substrate 1. To avoid trace conflict between the data line Data and the scan line, the data line Data can be disposed in the fourth metal layer m3.

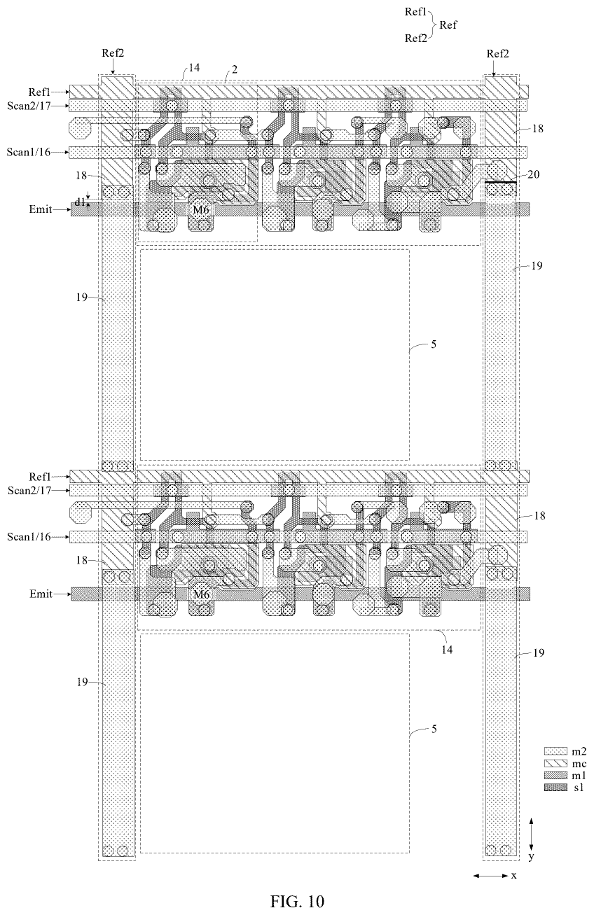

Regarding the second reset sub-line Ref2, in a feasible implementation, as shown in FIG. 10, FIG. 10 is a schematic diagram of a further film layer structure of a display panel provided by an embodiment of the present disclosure, the second reset sub-line Ref2 includes a first line segment 18 and a second line segment 19 that are electrically connected to each other. The first line segment 18 is located in the second metal layer mc, and the second line segment 19 is located in the third metal layer m2.

As mentioned above, the impedance of the third metal layer m2 is smaller than the impedance of the second metal layer mc. Therefore, designing the second reset sub-line Ref2 to switch between the second metal layer mc and the third metal layer m2 can reduce the overall load of the second reset sub-line Ref2.

In some implementations, the embodiments of the present disclosure can be applied to transparent display. In the transparent display panel, the display panel further includes light-transmitting regions 5, and at least some of the light-transmitting regions 5 are located on one side of the pixel circuit group 14 in the second direction y. For example, the pixel circuit group 14 and the light-transmitting region 5 are alternately arranged in the second direction y. Along the first direction x, the first line segment 18 at least overlaps with the pixel circuit group 14, and the second line segment 19 at least overlaps with the light-transmitting region 5. That is, the first line segment 18 is located on one side of the pixel circuit group 14, and the second line segment 19 is located on one side of the light-transmitting region 5. This can avoid trace conflicts between the second line segment 19 and the scan line.

In other optional implementations of the present disclosure, the second reset sub-line Ref2 may also be located only in the second metal layer mc, and then some line segments can be disposed in parallel on the second reset sub-line Ref2. In this way, the overall load of the reset line Ref can also be reduced. Exemplarily, these line segments disposed in parallel can be located in the third metal layer m2.

When the second reset sub-line Ref2 includes the first line segment 18 and the second line segment 19, in a feasible implementation, referring to FIGS. 2, 3, and 10, the pixel circuit 2 further includes a first light-emitting control transistor M6. The first light-emitting control transistor M6 has a gate electrically connected to a light-emitting control line Emit, a first electrode electrically connected to a first power line PVDD, and a second electrode electrically connected to the first electrode of the driving transistor M1.

The light-emitting control line Emit extends along the first direction x and is located on one side of the first scan line Scan1 away from the second scan line Scan2. The light-emitting control line Emit is located in the first metal layer m1, and in the direction perpendicular to the plane of the substrate 1, the light-emitting control line Emit does not overlap with the first line segment 18.

The first metal layer m1 and the second metal layer mc are usually separated by only a thin insulating layer. The light-emitting control line Emit is located in the first metal layer m1, and the first line segment 18 is located in the second metal layer mc. By not overlapping the light-emitting control line Emit with the first line segment 18, it is possible to avoid the light-emitting control line Emit and the first line segment 18 from generating a large coupling therebetween to increase the load of the light emitting control line Emit. In other words, the position where the first line segment 18 switches to the second line segment 19 is on the side of the light-emitting control line Emit close to the first scan line Scan1. In the direction perpendicular to the plane of the substrate 1, the light-emitting control line Emit overlaps with the second line segment 19.

Further, referring to FIG. 10, along the second direction y, a distance between the first line segment 18 and the light-emitting control line Emit is greater than or equal to 0.8 μm, thereby leaving a margin for process error. As such, even if the actual position(s) of the first line segment 18 and/or the light-emitting control line Emit shift(s) due to process precision or other factors, there will still be a certain distance between them, and they may not overlap.

In a feasible implementation, referring to FIG. 10, the second line segment 19 includes a first edge 20. The first edge 20 is located between the first scan line Scan1 and the light-emitting control line Emit, and a distance between the first edge 20 and the first scan line Scan1 is greater than a distance between the first edge 20 and the light-emitting control line Emit.

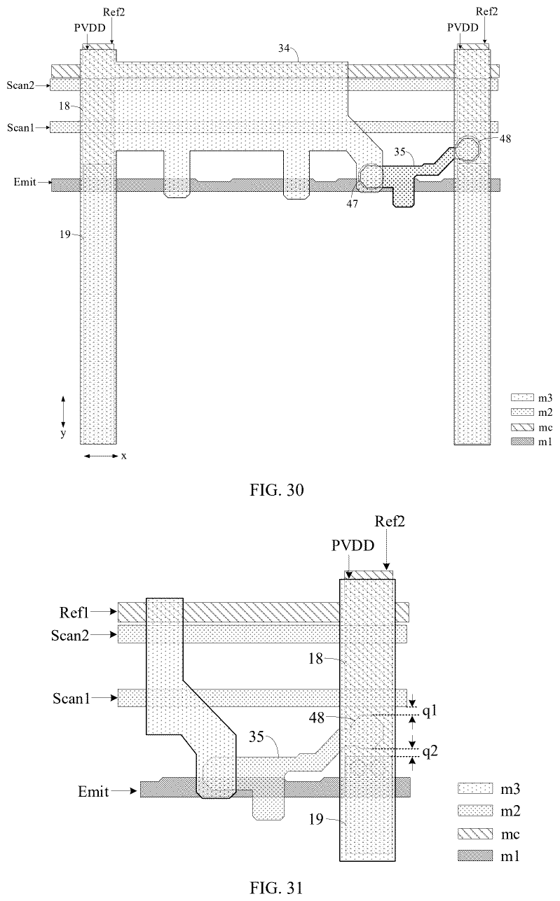

With this arrangement, on the one hand, the risk of short circuit between the second line segment 19 and the first part 16 of the first scan line Scan1 can be avoided, and on the other hand, in conjunction with FIG. 30, accommodation space can be provided between the second line segment 19 and the first scan line Scan1 for a third via-hole 48 between a seventh connection line 35 and the first power line PVDD. The details of this part will be described in subsequent embodiments.

In addition, the positions of the first edges 20 of the second line segments 19 in different second reset sub-lines Ref2 may vary. For example, when the third via-holes 48 do not need to be disposed between the second line segments 19 in some of the second reset sub-lines Ref2 and the first scan line Scan1, the distance between the first edges 20 of these second line segments 19 and the first scan line Scan can be reduced, thereby increasing the length ratio of the second line segment 19 in the entire second reset sub-line Ref2 and reducing the load of the second reset sub-line Ref2 to a greater extent.

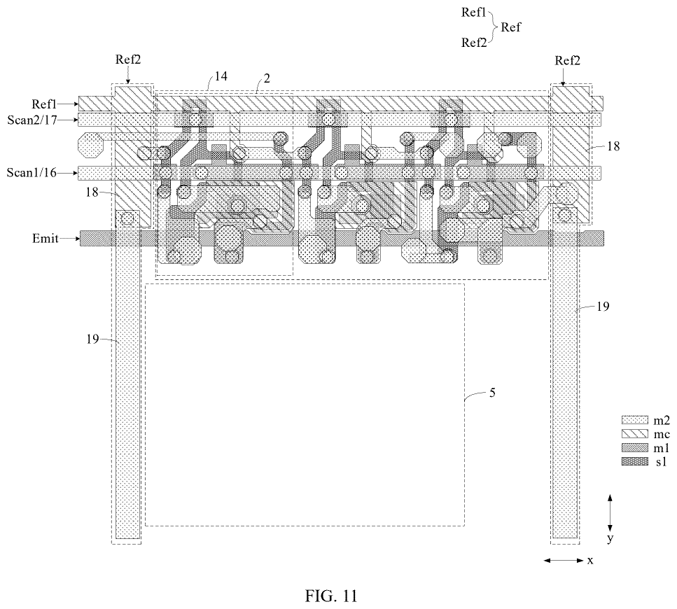

In a feasible implementation, as shown in FIG. 11, FIG. 11 is a schematic diagram of a further film layer structure of a display panel provided by an embodiment of the present disclosure, along the first direction x, a line width of the second line segment 19 is smaller than a line width of the first line segment 18.

On the premise of using the second line segment 19 to make the second reset sub-line Ref2 have a better load, the line width of the second line segment 19 can be designed to be slightly smaller. In this way, the wiring space occupied by the second line segment 19 can be compressed, and in turn the saved space is used to accommodate other metal trace.

In some implementations, the embodiments of the present disclosure can be applied to transparent display. In the transparent display panel, referring to FIG. 11, the display panel further includes light-transmitting regions 5, and at least some of light-transmitting regions 5 are located on one side of the pixel circuit group 14 in the second direction y, for example, the pixel circuit group 14 and the light-transmitting region 5 are alternately arranged in the second direction y. Reducing the line width of the second line segment 19 can release some space as the light-transmitting region 5, that is, increase the length of the light-transmitting region 5 in the first direction x and improve the transmittance of the display panel.

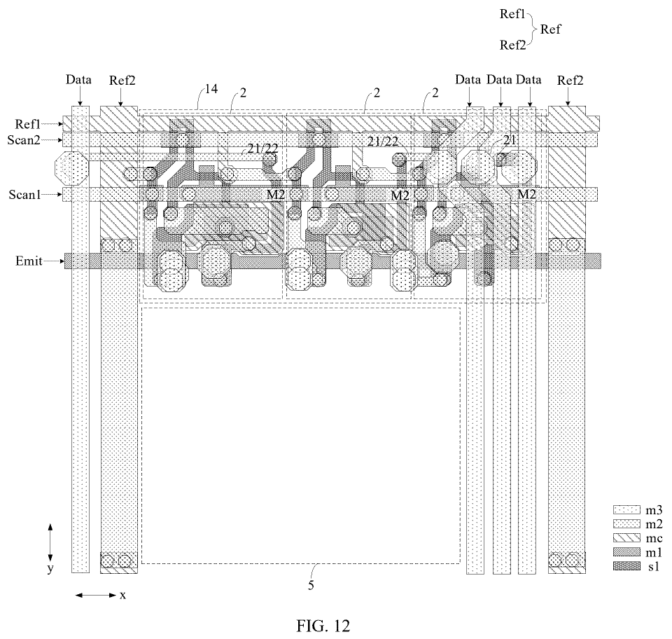

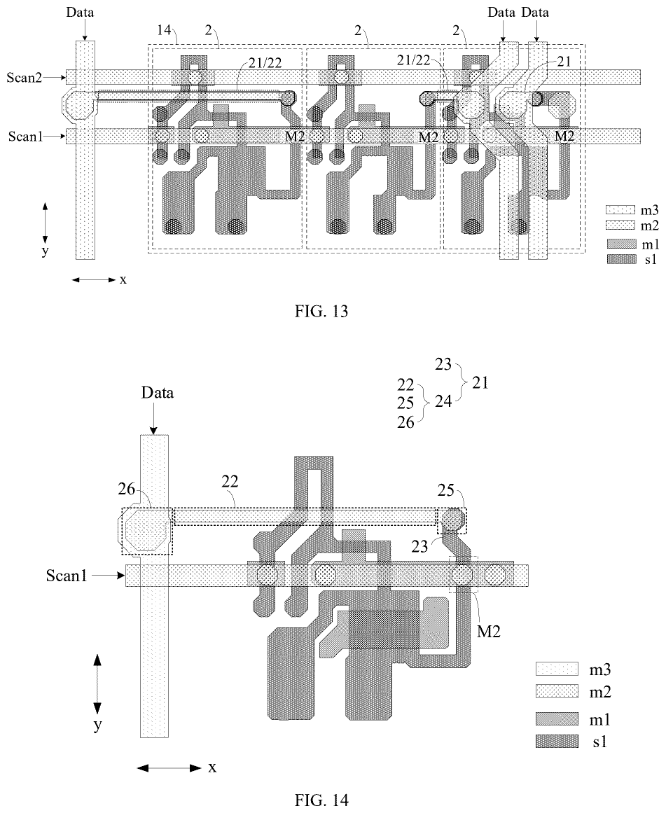

In a possible implementation, as shown in FIGS. 12 and 13, FIG. 12 is a schematic diagram of a further film layer structure of a display panel provided by an embodiment of the present disclosure, and FIG. 13 is a schematic diagram of a further film layer structure of a display panel provided by an embodiment of the present disclosure. The display panel includes a pixel circuit group 14 including multiple pixel circuits 2 arranged along the first direction x.

The data writing transistor M2 is electrically connected to the data line Data through a fifth connection line 21, and at least some fifth connection lines 21 each include a first sub-line segment 22 extending along the first direction x. In the pixel circuit group 14, the first sub-line segments 22 corresponding to at least two pixel circuits 2 are arranged along the first direction x.

Regarding the fifth connection line 21, as shown in FIG. 14, FIG. 14 is a schematic diagram of a further film layer structure of a display panel provided by an embodiment of the present disclosure, the fifth connection line 21 includes a first connection line segment 23 and a second connection line segment 24. The first connection line segment 23 is located in the semiconductor layer s1 and electrically connected to the first electrode of the data writing transistor M2. The second connection line segment 24 is located in the third metal layer m2. The second connection line segment 24 includes a first sub-line segment 22, a second sub-line segment 25, and a third sub-line segment 26. The second sub-line segment 25 is electrically connected to the first connection line segment 23 through a via-hole. The third sub-line segment 26 is electrically connected to the data line Data through a via-hole, and the first sub-line segment 22 is connected between the second sub-line segment 25 and the third sub-line segment 26. Along the second direction y, a width of the first sub-line segment 22 is less than a width of the second sub-line segment 25, and the width of the first sub-line segment 22 is less than a width of the third sub-line segment 26.

When the first sub-line segments 22 corresponding to the at least two pixel circuits 2 in the pixel circuit group 14 are arranged along the first direction x, the at least two first sub-line segments 22 only need to occupy one trace width in the second direction y, which in turn reduces the layout space occupied by the pixel circuit group 14 in the longitudinal direction and improves the PPI.

In some implementations, the embodiments of the present disclosure can be applied to transparent display. In the transparent display panel, the display panel further includes light-transmitting regions 5, and at least some of the light-transmitting regions 5 are located on one side of the pixel circuit group 14 in the second direction y, for example, the pixel circuit group 14 and the light-transmitting region 5 are alternately arranged in the second direction y. With the above structure, the layout space occupied by the pixel circuit group 14 in the longitudinal direction is reduced, and the released space can be used as a light-transmitting area, which can increase the longitudinal size of the light-transmitting region 5 in the second direction y and improve the transmittance of the display panel.

The extension lengths of the at least two first sub-line segments 22 arranged along the first direction x may be different.

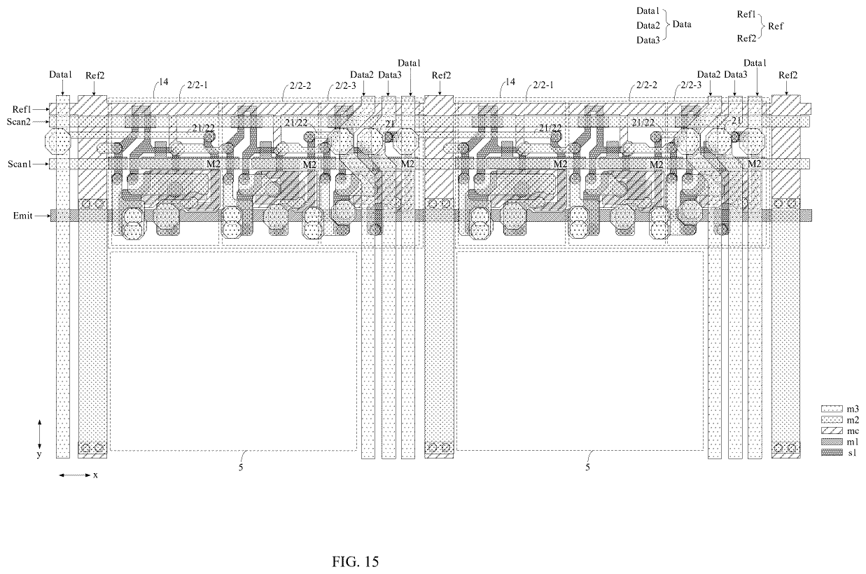

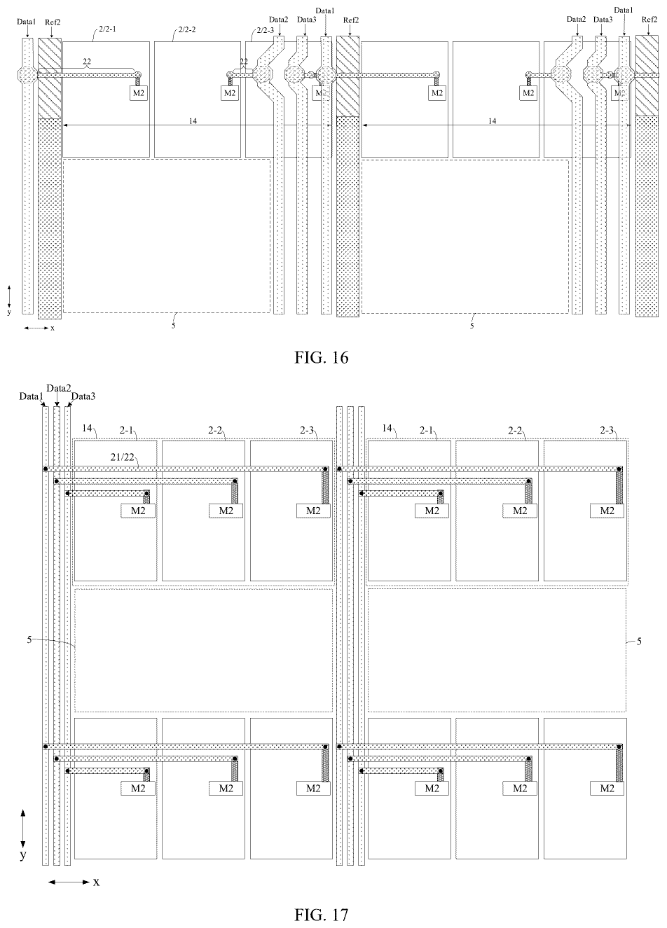

In a feasible implementation, as shown in FIGS. 15 and 16, FIG. 15 is a schematic diagram of a further film layer structure of a display panel provided by an embodiment of the present disclosure, and FIG. 16 is another structural schematic diagram of a display panel provided by an embodiment of the present disclosure. The pixel circuits 2 include a first pixel circuit 2-1, a second pixel circuit 2-2, and a third pixel circuit 2-3. The data lines Data include a first data line Data1 electrically connected to the first pixel circuit 2-1, a second data line Data2 electrically connected to the second pixel circuit 2-2, and a third data line Data3 electrically connected to the third pixel circuit 2-3.

The display panel includes a pixel circuit group 14 and light-transmitting regions 5. The pixel circuit group 14 includes a first pixel circuit 2-1, a second pixel circuit 2-2, and a third pixel circuit 2-3 arranged along the first direction x. At least some of the light-transmitting regions 5 are located on one side of the pixel circuit group 14 in the second direction y, and the second direction y intersects with the first direction x.

For the data lines Data connected to the same pixel circuit group 14, the first data line Data1 is located on a first side of the light-transmitting region 5 in the first direction x, and the second data line Data2 and the third data line Data3 are located on a second side of the light-transmitting region 5 in the first direction x.

For a transparent display panel, in a related design, as shown in FIG. 17, FIG. 17 is a structural schematic diagram of a display panel in the related art, three data lines Data connected to the pixel circuit group 14 are all located on the same side of the light-transmitting region 5. In this design, when the three pixel circuits 2 are electrically connected to the corresponding data lines Data through the fifth connection lines 21, the fifth connection lines 21 need to be led to the same side to avoid each other, and the first sub-line segments 22 in the at least two of the fifth connection lines 21 overlap in the second direction y, so that the first sub-line segments 22 as a whole need to occupy at least two trace widths in the longitudinal direction.

However, in the embodiments of the present disclosure, the three data lines Data connected to the pixel circuit group 14 are respectively located on two sides of the light-transmitting region 5. When the pixel circuit 2 is connected to the data line Data, it is at least ensured that the first sub-line segments 22 in two fifth connection lines 21 are led in different directions, which in turn enables the at least two first sub-line segments 22 to be arranged along the first direction x, compressing the trace width required to be occupied by the three first sub-line segments 22 as a whole in the longitudinal direction.

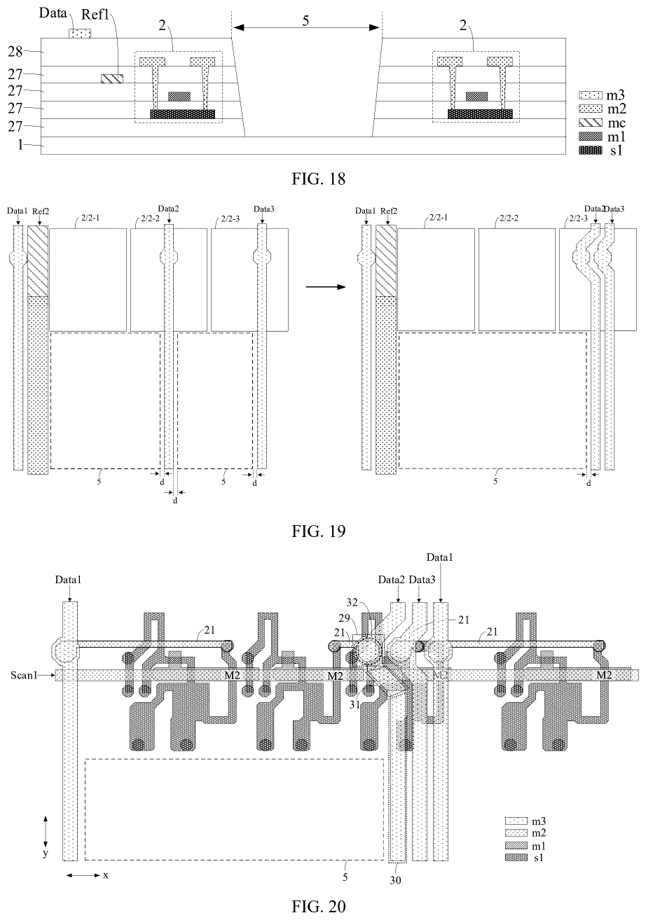

In addition, the three data lines Data connected to the pixel circuit group 14 are respectively located on two sides of the light-transmitting region 5, which also can increase the light-transmitting area. As shown in FIG. 18, FIG. 18 is a schematic diagram of a cross-sectional structure of a display panel provided by an embodiment of the present disclosure. The display panel includes an inorganic layer 27 and an organic layer 28. The inorganic layer 27 may include an inorganic insulating layer and the like, for example, an inorganic insulating layer between the semiconductor layer s1 and the first metal layer m1, an inorganic insulating layer between the first metal layer m1 and the second metal layer mc, and an inorganic insulating layer between the second metal layer mc and the third metal layer m2. The organic layer 28 may include a planarization layer and the like, for example, a planarization layer between the third metal layer m2 and the fourth metal layer m3. In order to improve the transmittance of the light-transmitting region 5, the inorganic layer 27 and the organic layer 28 in the light-transmitting region 5 may be designed to be dug out. In other words, the position of the light-transmitting region 5 is the position of the dug-out hole of the inorganic layer 27 and the organic layer 28, and the edge of the hole-digging region may be defined as the edge of the light-transmitting region 5.

In the process of hole-digging, due to the limitation of process precision, there is a certain avoidance distance d between the hole-digging region and the metal trace. In conjunction with FIG. 19, FIG. 19 is an arrangement comparison diagram of data lines provided by an embodiment of the present disclosure, the three data lines Data connected to the pixel circuit group 14 are respectively located on two sides of the light-transmitting region 5. Along the first direction x, the avoidance distance d needed to be provided between the light-transmitting region 5 and the data lines Data is less. Correspondingly, the size of the light-transmitting region 5 in the first direction x can be designed to be larger, which in turn effectively increases the light-transmitting area.

Further, referring to FIGS. 15 and 16, the reset line Ref includes the second reset sub-line Ref2 extending along the second direction y, and two adjacent second reset sub-lines Ref2 are spaced from each other by the pixel circuit group 14.

In the direction perpendicular to the plane of the substrate 1, the third data line Data3 overlaps with the third pixel circuit 2-3, the third data line Data3 is located between the second data line Data2 and the second reset sub-line Ref2, and the first data line Data1 is located between the third data line Data3 and the second reset sub-line Ref2.

In this arrangement manner, in the direction perpendicular to the plane of the substrate 1, the fifth connection line 21 between the first pixel circuit 2-1 and the first data line Data1 may overlap with the second reset sub-line Ref2. That is, among the three first data lines Data1, the second data line Data2 and the third data line Data3 adjacent to each other, the second data line Data2 and the third data line Data3 are connected to the second pixel circuit 2-2 and the third pixel circuit 2-3 in the same pixel circuit group 14, and the first data line Data1 is connected to the first pixel circuit 2-1 in another pixel circuit group 14. In this design, the wiring manner is more reasonable, the data line Data has less influence on the light-transmitting area, and the first sub-line segments 22 in the at least two fifth connection lines 21 can be arranged along the first direction x.

In a possible implementation, as shown in FIG. 20, FIG. 20 is a schematic diagram of a further film layer structure of a display panel provided by an embodiment of the present disclosure, and the data writing transistor M2 is electrically connected to the data line Data through the fifth connection line 21.

At least some of the data lines Data include a third line segment 29, a fourth line segment 30, and a fifth line segment 31. The third line segment 29 is electrically connected to the fifth connection line 21 through a first via-hole 32. The fourth line segment 30 extends along the second direction y. The fifth line segment 31 is connected between the third line segment 29 and the fourth line segment 30, and an included angle is formed between an extending direction of the fifth line segment 31 and the second direction y.

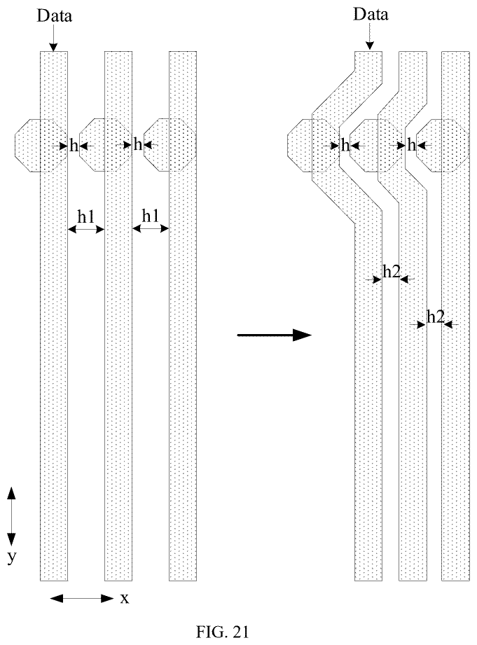

Generally, the width of the metal trace at a via-hole position is greater than the width at a non-via-hole position. It can be understood that adjacent data lines Data need to be spaced apart by a certain distance to avoid short circuit. In conjunction with FIG. 21, FIG. 21 is another structural comparison diagram of data lines provided by an embodiment of the present disclosure. Assuming that the distance to be spaced is h, if the entire data line Data extends linearly along the second direction y, the spacing distance h1 between adjacent data lines Data at the non-via-hole position is much larger than h, resulting in waste of wiring space.

However, in the embodiments of the present disclosure, at least some of the data lines Data are bent at the via-hole positions, thereby compressing the spacing distance h2 between adjacent data lines Data at the non-via-hole positions, making h2 closer to h. For example, h2 may be equal to h. As such, the line widths of different data lines Data at the non-via-hole positions can be arranged more tightly, and the wiring design is better.

When the embodiments of the present disclosure are applied to transparent display, referring to FIG. 20, the display panel include a light-transmitting region 5. The data lines Data being arranged more closely can increase the length of the light-transmitting region 5 in the first direction x, and the light-transmitting area can also be made larger.

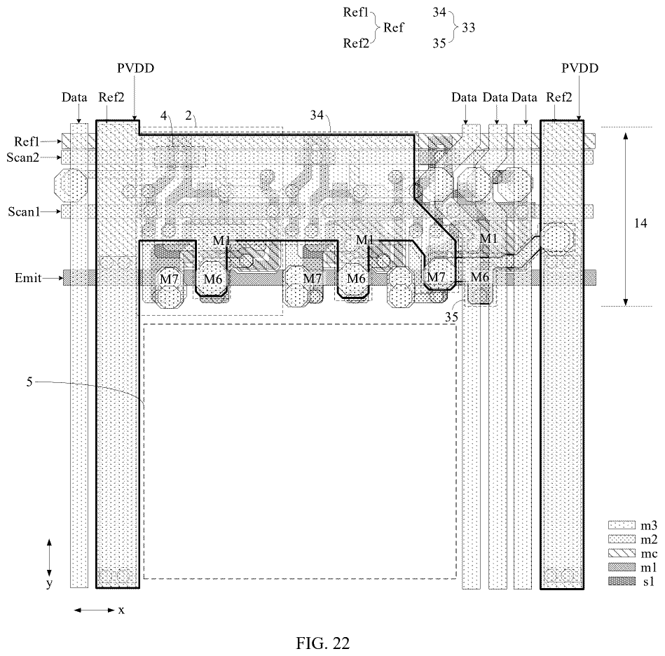

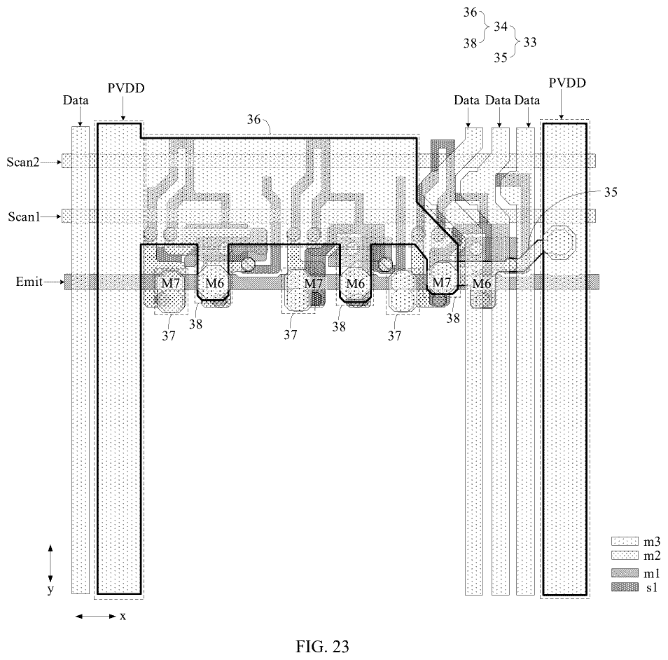

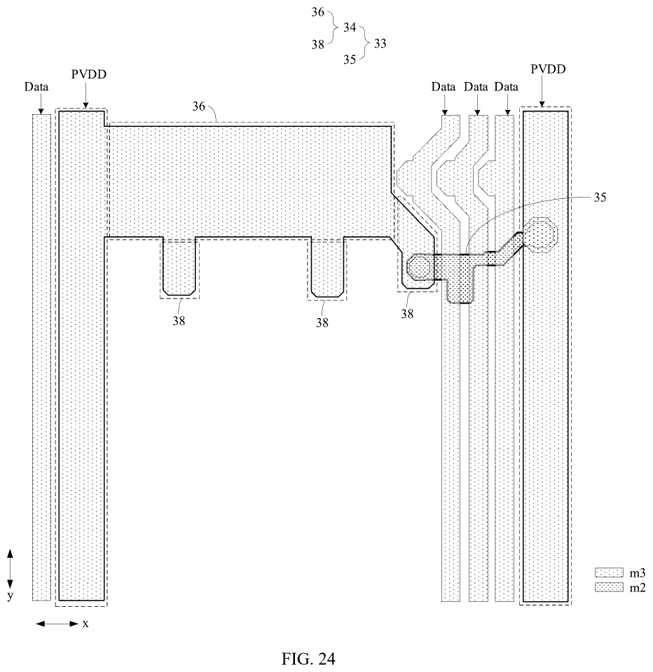

In a feasible implementation, in conjunction with FIG. 2, as shown in FIGS. 22 to 24, FIG. 22 is a schematic diagram of a further film layer structure of a display panel provided by an embodiment of the present disclosure, FIG. 23 is a schematic diagram of a further film layer structure of a display panel provided by an embodiment of the present disclosure, and FIG. 24 is a schematic diagram of a further film layer structure of a display panel provided by an embodiment of the present disclosure. The pixel circuit 2 further includes a first light-emitting control transistor M6. The first light-emitting control transistor M6 has a gate electrically connected to the light-emitting control line Emit, a first electrode electrically connected to the first power line PVDD, and a second electrode electrically connected to the first electrode of the driving transistor M1.

The first power line PVDD extends along the second direction y and is provided in the same layer as the data line Data. In the embodiments of the present disclosure, the first power line PVDD and the data line Data are both located in the fourth metal layer m3.

A first connection structure 33 is connected between two adjacent first power lines PVDD. The first connection structure 33 includes a sixth connection line 34 and a seventh connection line 35. The sixth connection line 34 and the first power line PVDD are provided in a same layer, and in the direction perpendicular to the plane of the substrate 1, the seventh connection line 35 overlaps with the data line Data and is provided in different layers from the data line Data.

The first power lines PVDD are connected by the first connecting structure 33 to form a grid-like structure as a whole, which can reduce the load. Since the first connection structure 33 overlaps with the data line Data, the seventh connection line 35 overlapping with the data line Data in the first connection structure 33 may be provided in different layers from the data line Data, and the sixth connection line 34 not overlapping with the data line Data is provided in the same layer as the data line Data, so as to realize reasonable wiring.

For a transparent display panel, in order to prevent the first connection structure 33 from affecting the transmittance, in the direction perpendicular to the plane of the substrate 1, the sixth connection line 34 and the seventh connection line 35 overlap with the pixel circuit group 14 and do not overlap with the light-transmitting region 5.

In a feasible implementation, in conjunction with FIG. 2 and FIGS. 22 to 24, the pixel circuit 2 further includes a gate reset module 4. The gate reset module 4 has a control terminal electrically connected to the second scan line Scan2, a first terminal electrically connected to the reset line Ref, and a second terminal electrically connected to the gate of the driving transistor M1.

The light-emitting control line Emit, the first scan line Scan1, and the second scan line Scan2 extend along the first direction x, and the light-emitting control line Emit is located on one side of the second scan line Scan2 away from the first scan line Scan1.

The sixth connection line 34 includes a third sub-part 36, and in the direction perpendicular to the plane of the substrate 1, the third sub-part 36 overlaps with the first scan line Scan1 and the second scan line Scan2, and along the second direction y, a width of the third sub-part 36 is greater than a distance between the second scan line Scan2 and the first scan line Scan1.

More specifically, in conjunction with FIG. 2 and FIGS. 22 to 24, the display panel further includes a second light-emitting control transistor M7. The second light-emitting control transistor M7 has a gate electrically connected to the light-emitting control line Emit, a first electrode electrically connected to the second electrode of the driving transistor M1, and a second electrode electrically connected to the light-emitting element 3. In order to improve connection reliability, the second electrode of the second light-emitting control transistor M7 may be electrically connected to the light-emitting element 3 through an eighth connection line 37. The eighth connection line 37 is located in the fourth metal layer m3 and provided in the same layer as the first power line PVDD.

Based on the presence of the eighth connection line 37, the sixth connection line 34 may be designed to include a third sub-part 36 and fourth sub-parts 38 that are electrically connected to each other. The third sub-part 36 is located on one side of the eighth connection line 37 in the second direction y, the fourth sub-parts 38 are located on one side of the eighth connection line 37 in the first direction x, and at least some of the fourth sub-parts 38 are electrically connected to the first light-emitting control transistor M6, so that the sixth connection line 34 and the eighth connection line 37 can avoid each other.

Based on this, in the embodiments of the present disclosure, when designing the third sub-part 36, a width of the third sub-part 36 in the second direction y is designed to be greater than a distance between the first scan line Scan1 and the second scan line Scan2, so as to reduce the load of the sixth connection line 34 as much as possible.

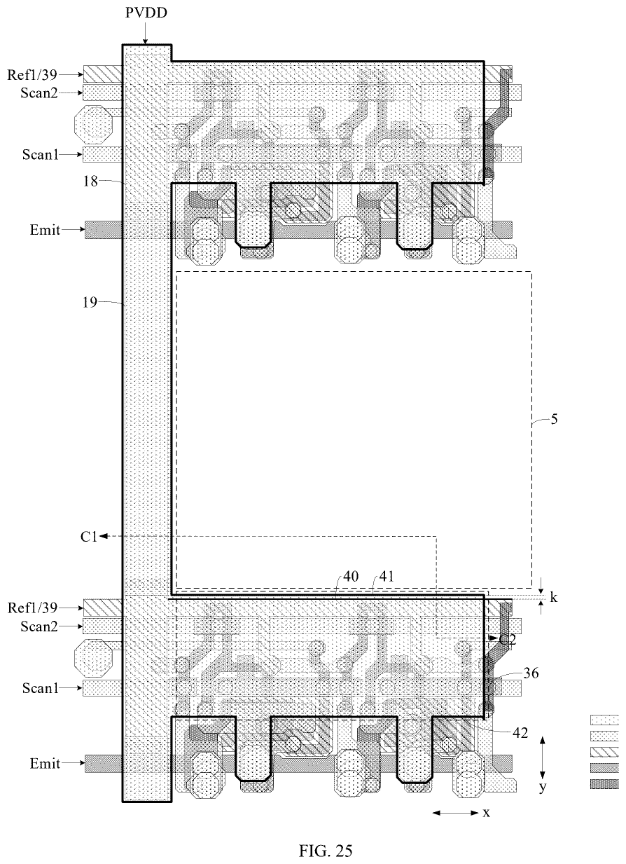

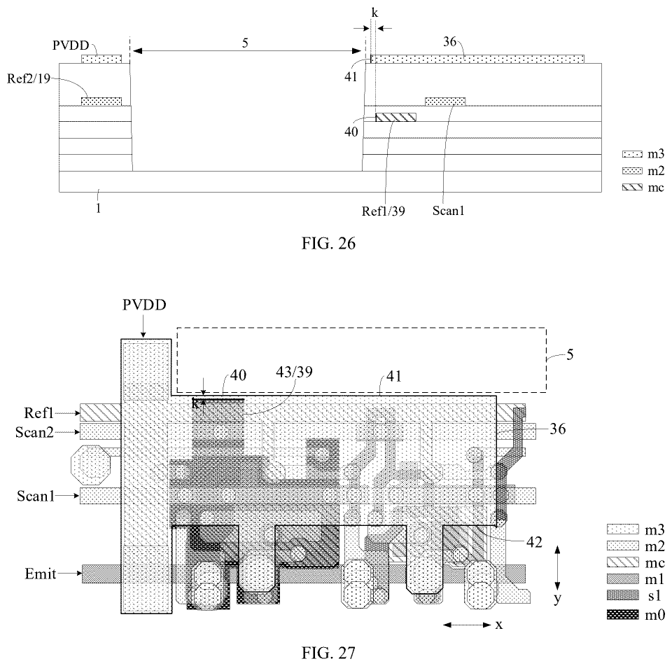

Further, as shown in FIGS. 25 and 26, FIG. 25 is a schematic diagram of a further film layer structure of a display panel provided by an embodiment of the present disclosure, and FIG. 26 is a cross-sectional view taken along a C1-C2 direction in FIG. 25. The display panel further includes a pixel circuit group 14 and light-transmitting regions 5. The pixel circuit group 14 includes multiple pixel circuits 2 arranged along the first direction x, and at least some of the light-transmitting regions 5 are located on one side of the pixel circuit group 14 in the second direction y.

The display panel further includes a first metal 39. The first metal 39 is located between the third sub-part 36 and the substrate 1, and a distance between the first metal 39 and the light-transmitting region 5 is less than a distance between another metal between the third sub-part 36 and the substrate 1 and the light-transmitting region 5.

The first metal 39 includes a second edge 40 close to the light-transmitting region 5. The third sub-part 36 includes a third edge 41 close to the light-transmitting region 5, and in the direction perpendicular to the plane of the substrate 1, a distance k between a projection of the third edge 41 and a projection of the second edge 40 is less than or equal to 1.2 μm.

The third sub-part 36 includes the third edge 41 and a fourth edge 45 opposite to each other in the second direction y. The third edge 41 is close to the light-transmitting region 5, and the fourth edge 45 is close to the eighth connection line 37.

Taking the third sub-part 36 being located in the fourth metal layer m3 as an example, a plurality of metal layers, for example, the first metal layer m1, the second metal layer mc, and the third metal layer m2, are included between the substrate 1 and the fourth metal layer m3, and each of the metal layers includes a plurality of metal traces. The first metal 39 is a metal trace in these metal layers which is closest to the light-transmitting region 5 on one side of the third edge 41. In other words, the film layer between the substrate 1 and the fourth metal layer m3 is a first film layer. The first film layer includes a plurality of metal layers, and the first metal 39 is located in some metal layer of the first film layer. A distance between the first metal 39 and the light-transmitting region 5 on one side of the third edge 41 is greater than a distance between other metal traces in the metal layer in which the first metal 39 is located and the light-transmitting region 5, and is further greater than a distance between metal traces in other metal layers in the first film layer and the light-transmitting region 5.

It should be noted that although FIG. 25 is a schematic diagram of taking the first metal 39 as the first reset line Ref as an example, in other structures, the first metal 39 may also be another metal structure. For example, as shown in FIG. 27, FIG. 27 is a schematic diagram of a further film layer structure of a display panel provided by an embodiment of the present disclosure. The display panel further includes a fifth metal layer m0 located on one side of the semiconductor layer s1 away from the first metal layer m1. The fifth metal layer m0 includes a shielding metal 43, and in the direction perpendicular to the plane of the substrate 1, the shielding metal 43 overlaps with the channels of at least some of the transistors to prevent ambient light from irradiating the channels and affecting the formation of the transistors. When an edge of the shielding metal 43 is closer to the light-transmitting region 5, the first metal 39 may also be the shielding metal 43.

As mentioned above, the inorganic layer 27 and the organic layer 28 in the light-transmitting region 5 are designed to be dug out, and the edge of the light-transmitting region 5 can be regarded as the edge of the hole-digging region. Therefore, a distance between the light-transmitting region 5 and an edge of the metal trace can be defined by a distance between the edge of the hole-digging region and the edge of the metal trace.

The distance k between the third edge 41 of the third sub-part 36 and the second edge 40 of the first metal 39 is less than or equal to 1.2 μm, including a case in which the third edge 41 coincides with the second edge 40, a case in which the third edge 41 is located on one side of the second edge 40 away from the fourth edge 45, and a case in which the third edge 41 is located on one side of the second edge 40 close to the fourth edge 45. The limitation on the distance between the third edge 41 and the second edge 40 can prevent the third sub-part 36 from extending too far beyond the first metal 39 to block the light-transmission area. Further, the third edge 41 may coincide with the second edge 40.

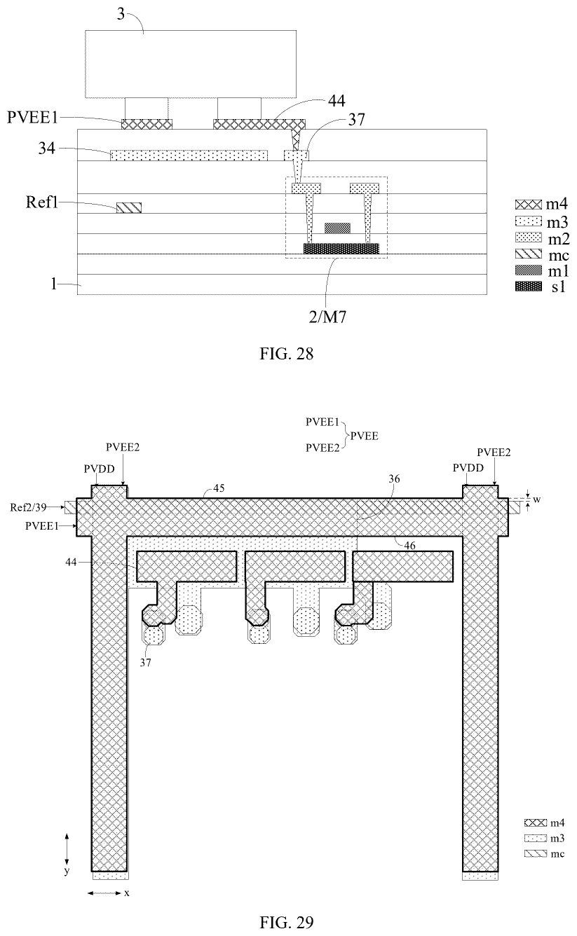

In addition, in conjunction with FIGS. 28 and 29, FIG. 28 is a schematic diagram of another cross-sectional structure of a display panel provided by an embodiment of the present disclosure, and FIG. 29 is a schematic diagram of a further film layer structure of a display panel provided by an embodiment of the present disclosure. The display panel may further include a sixth metal layer m4 located on one side of the fourth metal layer m3 away from the substrate 1.

The sixth metal layer m4 includes a second power line PVEE and a bonding part 44. The second power line PVEE includes a first power sub-line PVEE1 and a second power sub-line PVEE2 electrically connected to each other. The first power sub-line PVEE1 extends along the first direction x. In the direction perpendicular to the plane of the substrate 1, the first power sub-line PVEE1 overlaps with the third sub-part 36. The second power sub-line PVEE2 extends along the second direction y, and overlaps with the first power line PVDD in the direction perpendicular to the plane of the substrate 1.

The bonding part 44 is electrically connected to the eighth connection line 37. The bonding part 44 is further electrically connected to a first electrode of the light-emitting element 3 (not shown), and the first power sub-line PVEE1 is electrically connected to a second electrode of the light-emitting element 3 (not shown).

The first power sub-line PVEE1 includes the fourth edge 45 and a fifth edge 46 opposite to each other in the second direction y, and the fourth edge 45 is located on one side of the fifth edge 46 away from the bonding part 44. In the direction perpendicular to the plane of the substrate 1, a distance w between a projection of the fourth edge 45 and the projection of the second edge 40 may also be set to be less than or equal to 1.2 μm, so that the fourth edge 45 tends to coincide with the second edge 40, avoiding the second power line PVEE from extending too far beyond the first metal 39 and thus occupy the light-transmitting area.

In a feasible implementation, as shown in FIG. 30, FIG. 30 is a further structural schematic diagram of a display panel provided by an embodiment of the present disclosure. The seventh connection line 35 is electrically connected to the sixth connection line 34 through a second via-hole 47, and the seventh connection line 35 is electrically connected to the first power line PVDD through the third via-hole 48. A distance between the third via-hole 48 and the first scan line Scan1 is less than a distance between the second via-hole 47 and the first scan line Scan1.

As mentioned above, the second reset sub-line Ref2 includes the first line segment 18 and the second line segment 19 provided in different layers. The second line segment 19 and the seventh connection line 35 are provided in the same layer and are located in the third metal layer m2.

In the embodiments of the present disclosure, in the direction perpendicular to the plane of the substrate 1, the power line overlaps with the second reset sub-line Ref2. Compared with the second via-hole 47, the third via-hole 48 is closer to the first scan line Scan1, which can leaves a larger wiring space for the second line segment 19, increasing a length ratio of the second line segment 19 in the second reset sub-line Ref2, and thus being conducive to greatly reducing the load of the second reset sub-line Ref2.

Further, referring to FIG. 27, the reset line Ref includes a first reset sub-line and a second reset sub-line Ref2 electrically connected to each other. The first reset sub-line Ref1 extends along the first direction x, the second reset sub-line Ref2 extends along the second direction y, and in the direction perpendicular to the plane of the substrate 1, the first power line PVDD overlaps with the second reset sub-line Ref2.

The second reset sub-line Ref2 includes a first line segment 18 and a second line segment 19 provided in different layers. The second line segment 18 and the seventh connection line 35 are provided in the same layer, and the third via-hole 48 is located between the first scan line Scan1 and the second line segment 19 to provide a reasonable setting space for the third via-hole 48.

Further, as shown in FIG. 31, FIG. 31 is a schematic diagram of a further film layer structure of a display panel provided by an embodiment of the present disclosure. A distance q1 between the third via-hole 48 and the first scan line Scan1 is greater than or equal to 2.5 μm, and a distance q2 between the third via-hole 48 and the second line segment 19 is greater than or equal to 2.5 μm, so that there is a sufficient distance between the third via-hole 48 and the first scan line Scan1, a sufficient distance between the third via-hole 48 and the second line segment 19, leaving a margin for process error and thus avoiding the risk of short circuit caused by factors such as process error and the like.

In the embodiments of the present disclosure, q1 and q2 may be respectively set to be equal to 2.5 μm, so as to compress the distance between the third via-hole 48 and the first scan line Scan1 and the distance between the third via-hole 48 and the second line segment 19 as much as possible on the premise of ensuring that a margin is left for the process error, which in turn makes a larger wiring space for the second line segment 19 and increases a length of the second line segment 19 as much as possible.

In the embodiments of the present disclosure, referring to FIG. 2, the pixel circuit 2 further includes a storage capacitor Cst. The storage capacitor Cst has a first electrode plate electrically connected to the first power line PVDD, and a second electrode plate electrically connected to the gate of the driving transistor M1.

The following takes the structure of the film layer shown in FIG. 3 as an example to disassemble each of the film layers included in the structure, so as to more clearly illustrate the structure involved in the embodiments of the present disclosure.

The display panel includes the semiconductor layer s1, the first metal layer m1 located on one side of the semiconductor layer s1 away from the substrate 1, the second metal layer mc located on one side of the first metal layer m1 away from the semiconductor layer s1, the third metal layer m2 located on one side of the second metal layer mc away from the first metal layer m1, and the fourth metal layer m3 located on one side of the third metal layer m2 away from the substrate 1.

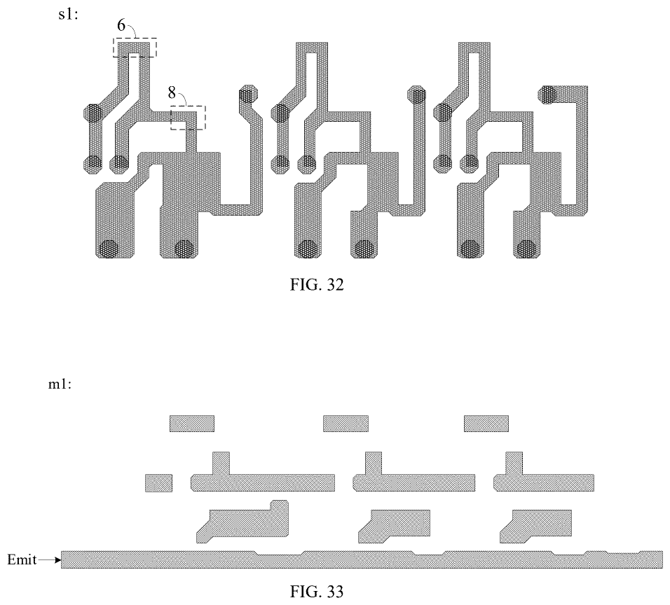

As shown in FIG. 32, FIG. 32 is a structural schematic diagram of a semiconductor layer s1 corresponding to FIG. 3. The semiconductor layer s1 includes structures such as the first connection line 6 and the second connection line 8.

As shown in FIG. 33, FIG. 33 is a structural schematic diagram of a first metal layer m1 corresponding to FIG. The first metal layer m1 includes structures such as the light-emitting control line Emit.

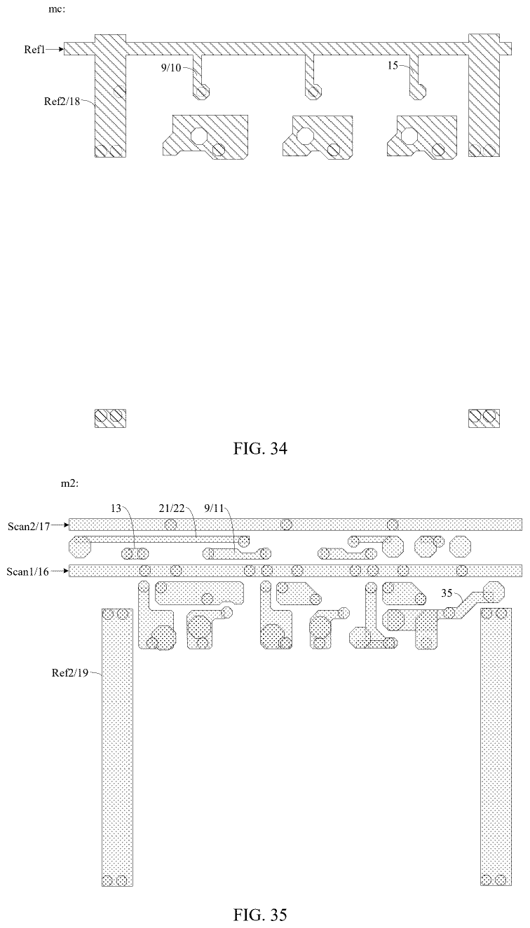

As shown in FIG. 34, FIG. 34 is a structural schematic diagram of a second metal layer mc corresponding to FIG. 3. The second metal layer mc includes structures such as the first reset sub-line Ref1, the first line segment 18 in the second reset sub-line Ref2, the first sub-part 10 in the third connection line 9, and the shielding part 15.

As shown in FIG. 35, FIG. 35 is a structural schematic diagram of the third metal layer m2 corresponding to FIG. 3. The third metal layer m2 includes structures such as the second sub-part 11 in the third connection line 9, the fourth connection line 13, the first part 16 in the first scan line Scan1, the second part 17 in the second scan line Scan2, the first sub-line segment 22 in the fifth connection line 21, the second line segment 19 in the second reset sub-line Ref2, and the seventh connection line 35.

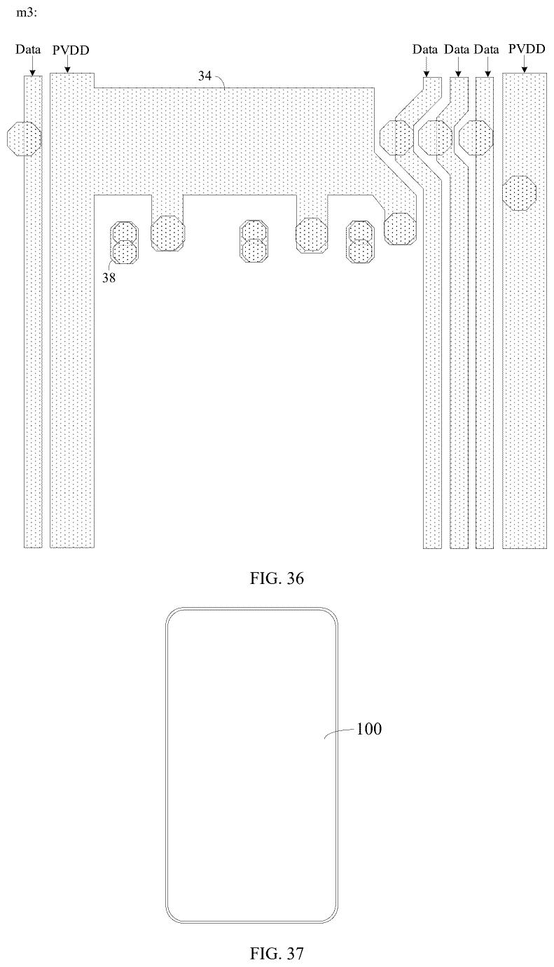

As shown in FIG. 36, FIG. 36 is a structural schematic diagram of the fourth metal layer m3 corresponding to FIG. 3. The fourth metal layer m3 includes structures such as the data line Data, the first power line PVDD, the sixth connection line 34, and the eighth connection line 37.

Based on the same inventive concept, an embodiment of the present disclosure further provides a display apparatus. As shown in FIG. 37, FIG. 37 is a structural schematic diagram of a display apparatus provided by an embodiment of the present disclosure. The display apparatus includes the above-mentioned display panel 100. The display apparatus shown in FIG. 37 is merely illustrative, and the display apparatus may be any electronic device having a display function, for example, a mobile phone, a tablet computer, a notebook computer, an e-book, a television and the like.

The above are merely the preferred embodiments of the present disclosure and are not intended to limit the present disclosure, and any modifications, equivalent substitutions, improvements and the like made within the spirit and principle of the present disclosure should be included within the scope of the present disclosure.

Finally, it should be noted that the above various embodiments are merely used to illustrate the technical solutions of the present disclosure, but not to limit the same. Although the present disclosure has been described in detail with reference to the above various embodiments, it should be understood by those skilled in the art that the technical solutions recited in the above various embodiments of the present disclosure may still be modified, or some or all of the technical features in them may be equivalently replaced. These modifications or substitutions do not make the essence of the corresponding technical solutions depart from the scope of the technical solutions in the various embodiments of the present disclosure.

What is claimed is:

1. A display panel, comprising a substrate and pixel circuits on one side of the substrate, wherein at least one of the pixel circuits comprises:
a driving transistor;
a data writing transistor having a gate electrically connected to a first scan line, a first electrode electrically connected to a data line, and a second electrode electrically connected to a first electrode of the driving transistor; and
an anode reset transistor having a gate electrically connected to the first scan line, a first electrode electrically connected to a reset line, and a second electrode electrically connected to a light-emitting element;
wherein the anode reset transistor and the data writing transistor of a same pixel circuit are electrically connected to a same first scan line.

2. The display panel according to claim 1, wherein,
the at least one the pixel circuits further comprises a gate reset module, the gate reset module comprises a first reset transistor and a second reset transistor, a gate of the first reset transistor and a gate of the second reset transistor are both electrically connected to a second scan line, a first electrode of the first reset transistor is electrically connected to the reset line, a second electrode of the first reset transistor is electrically connected to a first electrode of the second reset transistor through a first connection line, and a second electrode of the second reset transistor is electrically connected to a gate of the driving transistor;
the first scan line and the second scan line extend along a first direction; and
the reset line comprises a first reset sub-line extending along the first direction and located on one side of the second scan line away from the first scan line, and in a direction perpendicular to a plane of the substrate, the first reset sub-line overlaps with the first connection line.

3. The display panel according to claim 2, wherein,
the at least one of the pixel circuits further comprises a threshold compensation module, the threshold compensation module comprises a first compensation transistor and a second compensation transistor, a gate of the first compensation transistor and a gate of the second compensation transistor are both electrically connected to the first scan line, a first electrode of the first compensation transistor is electrically connected to a second electrode of the driving transistor, a second electrode of the first compensation transistor is electrically connected to a first electrode of the second compensation transistor through a second connection line, and a second electrode of the second compensation transistor is electrically connected to the gate of the driving transistor; and
at least one of the anode reset transistors in at least some of the pixel circuits is electrically connected to the first reset sub-line through a third connection line, and in the direction perpendicular to the plane of the substrate, the third connection line overlaps with the second connection line.

4. The display panel according to claim 3, wherein,
for a same third connection line, the pixel circuit where the anode reset transistor connected to the third connection line is located is adjacent to the pixel circuit where the second connection line overlapping with the third connection line is located in the first direction.

5. The display panel according to claim 3, wherein,
the display panel comprises a first metal layer, a second metal layer located on one side of the first metal layer away from the substrate, and a third metal layer located on one side of the second metal layer away from the substrate;
the gate of the driving transistor is located in the first metal layer, and the first reset sub-line is located in the second metal layer; and
the third connection line comprises a first sub-part and a second sub-part, the first sub-part is connected to the first reset sub-line, the second sub-part is connected between the first sub-part and the anode reset transistor, the first sub-part is located in the second metal layer, the second sub-part is located in the third metal layer, and in the direction perpendicular to the plane of the substrate, the first sub-part overlaps with the second connection line.

6. The display panel according to claim 5, wherein,
the first sub-part and the second sub-part are electrically connected through a first connection via-hole, and in the direction perpendicular to the plane of the substrate, the first connection via-hole overlaps with the second connection line.

7. The display panel according to claim 3, wherein,
the reset line further comprises a second reset sub-line extending along a second direction and electrically connected to the first reset sub-line, and the second direction intersects with the first direction; and
the pixel circuits comprise a first pixel circuit adjacent to the second reset sub-line, and the anode reset transistor in the first pixel circuit is electrically connected to the second reset sub-line through a fourth connection line.

8. The display panel according to claim 7, wherein,
the pixel circuits further comprise a second pixel circuit and a third pixel circuit;
the display panel comprises a pixel circuit group comprising the first pixel circuit, the second pixel circuit, and the third pixel circuit arranged along the first direction;
along the first direction, two adjacent second reset sub-lines are spaced from each other by the pixel circuit group; and
in the first pixel circuit, a distance between the anode reset transistor and the second reset sub-line is less than a distance between the data writing transistor and the second reset sub-line.

9. The display panel according to claim 8, wherein,
the second pixel circuit is electrically connected to the third connection line, and in the direction perpendicular to the plane of the substrate, the third connection line connected to the second pixel circuit overlaps with the second connection line in the first pixel circuit;
the third pixel circuit is electrically connected to the third connection line, and in the direction perpendicular to the plane of the substrate, the third connection line connected to the third pixel circuit overlaps with the second connection line in the second pixel circuit; and
the display panel further comprises a shielding part electrically connected to the reset line, and in the direction perpendicular to the plane of the substrate, the shielding part overlaps with the second connection line in the third pixel circuit.

10. The display panel according to claim 2, wherein,
the display panel comprises a first metal layer, a second metal layer located on one side of the first metal layer away from the substrate, and a third metal layer located on one side of the second metal layer away from the substrate;
the gate of the driving transistor is located in the first metal layer, and the first reset sub-line is located in the second metal layer;
the reset line further comprises a second reset sub-line extending along a second direction and electrically connected to the first reset sub-line, and the second direction intersects with the first direction; and
the second reset sub-line comprises a first line segment and a second line segment that are electrically connected to each other, and the first line segment is located in the second metal layer, and the second line segment is located in the third metal layer.

11. The display panel according to claim 10, wherein,
the at least one of the pixel circuits further comprises a first light-emitting control transistor having a gate electrically connected to a light-emitting control line, a first electrode electrically connected to a first power line, and a second electrode electrically connected to the first electrode of the driving transistor; and
the light-emitting control line extends along the first direction and is located on one side of the first scan line away from the second scan line, the light-emitting control line is located in the first metal layer, and in the direction perpendicular to the plane of the substrate, the light-emitting control line does not overlap with the first line segment.

12. The display panel according to claim 11, wherein,
along the second direction, a distance between the first line segment and the light-emitting control line is greater than or equal to 0.8 μm.

13. The display panel according to claim 11, wherein,
the second line segment comprises a first edge located between the first scan line and the light-emitting control line, and a distance between the first edge and the first scan line is greater than a distance between the first edge and the light-emitting control line.

14. The display panel according to claim 10, wherein,
along the first direction, a line width of the second line segment is smaller than a line width of the first line segment.

15. The display panel according to claim 1, wherein,
the display panel comprises a first metal layer, and the gate of the anode reset transistor and/or the gate of the data writing transistor are/is located in the first metal layer; and
the first scan line comprises a first part electrically connected to the gate of the anode reset transistor and/or the gate of the data writing transistor, and the first part is located on one side of the first metal layer away from the substrate.

16. The display panel according to claim 1, wherein,
the display panel comprises a pixel circuit group comprising multiple pixel circuits arranged along a first direction;
the data writing transistor is electrically connected to the data line through a fifth connection line, and at least some fifth connection lines each comprise a first sub-line segment extending along the first direction; and
in the pixel circuit group, the first sub-line segments corresponding to at least two pixel circuits are arranged along the first direction.

17. The display panel according to claim 1, wherein,
the pixel circuits comprises a first pixel circuit, a second pixel circuit, and a third pixel circuit; the data line comprises a first data line electrically connected to the first pixel circuit, a second data line electrically connected to the second pixel circuit, and a third data line electrically connected to the third pixel circuit;
the display panel comprises a pixel circuit group and light-transmitting regions, the pixel in circuit group comprises the first pixel circuit, the second pixel circuit, and the third pixel circuit arranged in a first direction, at least some of the light-transmitting regions are located on one side of the pixel circuit group in a second direction, and the second direction intersects with the first direction; and
for the data lines connected to a same pixel circuit group, the first data line is located on a first side of the light-transmitting region in the first direction, and the second data line and the third data line are located on a second side of the light-transmitting region in the first direction.

18. The display panel according to claim 17, wherein,
the reset line comprises a second reset sub-line extending along the second direction, and two adjacent second reset sub-lines are spaced from each other by the pixel circuit group; and
in a direction perpendicular to a plane of the substrate, the third data line overlaps with the third pixel circuit, the third data line is located between the second data line and the second reset sub-line, and the first data line is located between the third data line and the second reset sub-line.

19. The display panel according to claim 17, wherein,
the data writing transistor is electrically connected to the data line through a fifth connection line; and
at least some of the data lines each comprise a third line segment, a fourth line segment, and a fifth line segment, the third line segment is electrically connected to the fifth connection line through a first via-hole, the fourth line segment extends along the second direction, the fifth line segment is connected between the third line segment and the fourth line segment, and an included angle is formed between an extending direction of the fifth line segment and the second direction.

20. A display apparatus, comprising a display panel, wherein the display panel comprises a substrate and pixel circuits on one side of the substrate, wherein at least one of the pixel circuits comprises:
a driving transistor;
a data writing transistor having a gate electrically connected to a first scan line, a first electrode electrically connected to a data line, and a second electrode electrically connected to a first electrode of the driving transistor; and
an anode reset transistor having a gate electrically connected to the first scan line, a first electrode electrically connected to a reset line, and a second electrode electrically connected to a light-emitting element;
wherein the anode reset transistor and the data writing transistor of a same pixel circuit are electrically connected to a same first scan line.
